(19) United States
(12) Patent Application Publication
(10) Pub. No.: US 2025/0259687 A1
(43) Pub. Date: Aug. 14, 2025

(54) DATA READING METHOD AND APPARATUS, DEVICE, AND READABLE STORAGE MEDIUM

(71) Applicant: Tencent Technology (Shenzhen) Company Limited, Shenzhen (CN)

(72) Inventor: Zimu REN, Shenzhen (CN)

(73) Assignee: Tencent Technology (Shenzhen) Company Limited, Shenzhen (CN)

(21) Appl. No.: 19/169,081

(22) Filed: Apr. 3, 2025

Related U.S. Application Data
(63) Continuation of application No. PCT/CN2024/073958, filed on Jan. 25, 2024.

(30) Foreign Application Priority Data
Mar. 9, 2023 (CN) 202310254874.9

(51) Int. Cl. G11C 16/26; G11C 16/08

(52) U.S. Cl. CPC G11C 16/26; G11C 16/08

(57) ABSTRACT

A data reading method includes acquiring a first weight read request for requesting to read weight attribute data from storage and a first feature map read request for requesting to read feature map attribute data from the storage; acquiring a reference status identification indicating a status of a weight attribute register in a systolic array after a pre-defined elapsed time; based on the reference status identification satisfying a first pre-defined condition, reading the weight attribute data from the storage, and writing the weight attribute data to the systolic array in response to the first weight read request; and based on the reference status identification satisfying a second pre-defined condition, reading the feature map attribute data from the storage, and writing the feature map attribute data to the systolic array in response to the first feature map read request.

### CROSS-REFERENCE TO RELATED APPLICATIONS

This application is a continuation application of International Application No. PCT/CN2024/073958 filed on Jan. 25, 2024, which claims priority to Chinese Patent Application No. 202310254874.9 filed with the China National Intellectual Property Administration on Mar. 9, 2023, the disclosures of each being incorporated by reference herein in their entireties.

### FIELD

Embodiments of this application relate to the technical field of computers, and to a data reading method and apparatus, a device, and a readable storage medium.

### BACKGROUND

Peak computing power is an index for measuring computer performance in the technical field of computers. It refers to the maximum number of calculations that a processor can achieve within a unit of time, and the ability to read data from a storage is closely related to the peak computing power.

In the related art, there is an array structure including a plurality of rows and a plurality of columns of process engines (PEs), and the array structure is referred to as a systolic array. Data in the storage may be written to the systolic array and then calculated efficiently through the systolic array. When a condition of reading the data in the storage and writing the data to the systolic array is not satisfied, target data in the storage may be registered in a queue in response to a read request for the target data. When the condition of reading the data in the storage and writing the data to the systolic array is satisfied, the target data is taken out from the queue and transmitted to the systolic array.

A chip may be used as a carrier of an object having a data storage function, such as a storage or a queue. The queue may occupy some registering resources, which causes a large chip area.

### SUMMARY

According to an aspect of the disclosure, a data reading method, performed by an electronic device including a processor, a systolic array for performing calculations based on weight attribute data and feature map attribute data and a storage, wherein the systolic array includes a weight attribute register for registering the weight attribute data, and wherein the data reading method includes acquiring a first weight read request for requesting to read the weight attribute data from the storage and a first feature map read request for requesting to read the feature map attribute data from the storage; acquiring a reference status identification indicating a status of the weight attribute register in the systolic array after a pre-defined elapsed time; based on the reference status identification satisfying a first pre-defined condition, reading the weight attribute data from the storage, and writing the weight attribute data to the systolic array in response to the first weight read request; and based on the reference status identification satisfying a second pre-defined condition, reading the feature map attribute data from the storage, and writing the feature map attribute data to the systolic array in response to the first feature map read request.

According to an aspect of the disclosure, a storage system includes a storage configured to store weight attribute data and feature map attribute data; a systolic array including a weight attribute register and that is configured to perform calculations based on the weight attribute data and the feature map attribute data; and a processor operatively connected to the storage and the systolic array, wherein the processor is configured to acquire a first weight read request for requesting to read the weight attribute data from the storage and a first feature map read request for requesting to read the feature map attribute data from the storage; acquire a reference status identification indicating a status of the weight attribute register in the systolic array after a pre-defined elapsed time; based on the reference status identification satisfying a first pre-defined condition, read the weight attribute data from the storage, and write the weight attribute data to the systolic array in response to the first weight read request; and based on the reference status identification satisfying a second pre-defined condition, read the feature map attribute data from the storage, and write the feature map attribute data to the systolic array based on the first feature map read request.

According to an aspect of the disclosure, a non-transitory computer-readable storage medium, storing computer code which, when executed by at least one processor, causes the at least one processor to at least acquire a first weight read request for requesting to read weight attribute data from storage, and a first feature map read request for requesting to read feature map attribute data from the storage; acquire a reference status identification indicating a status of a weight attribute register in a systolic array after a pre-defined elapsed time; based on the reference status identification satisfying a first pre-defined condition, read the weight attribute data from the storage, and write the weight attribute data to the systolic array in response to the first weight read request; and based on the reference status identification satisfying a second pre-defined condition, read the feature map attribute data from the storage, and write the feature map attribute data to the systolic array in response to the first feature map read request.

### BRIEF DESCRIPTION OF THE DRAWINGS

To describe the technical solutions of some embodiments of this disclosure more clearly, the following briefly introduces the accompanying drawings for describing some embodiments. The accompanying drawings in the following description show only some embodiments of the disclosure, and a person of ordinary skill in the art may still derive other drawings from these accompanying drawings without creative efforts. In addition, one of ordinary skill would understand that aspects of some embodiments may be combined together or implemented alone.

FIG. 1 is a schematic diagram of some embodiments environment of a data reading method according to some embodiments.

FIG. 2 is a schematic diagram of data loading a systolic array according to some embodiments.

FIG. 3 is a flowchart of a data reading method according to some embodiments.

FIG. 4 is a schematic diagram of updating a status identification according to some embodiments.

FIG. 5 is a schematic diagram of determining whether a sub-request is valid according to some embodiments.

FIG. 6 is a schematic diagram of a data acquisition process according to some embodiments.

FIG. 7 is an architectural diagram of a storage system according to some embodiments.

FIG. 8 is a schematic structural diagram of an arbiter unit according to some embodiments.

FIG. 9 is a schematic structural diagram of a data reading apparatus according to some embodiments.

FIG. 10 is a schematic structural diagram of a terminal device according to some embodiments.

FIG. 11 is a schematic structural diagram of a server according to some embodiments.

FIG. 12 is an architectural diagram of another storage system according to some embodiments.

### DESCRIPTION OF EMBODIMENTS

To make the objectives, technical solutions, and advantages of the present disclosure clearer, the following further describes the present disclosure in detail with reference to the accompanying drawings. The described embodiments are not to be construed as a limitation to the present disclosure. All other embodiments obtained by a person of ordinary skill in the art without creative efforts shall fall within the protection scope of the present disclosure.

In the following descriptions, related “some embodiments” describe a subset of all possible embodiments. However, it may be understood that the “some embodiments” may be the same subset or different subsets of all the possible embodiments, and may be combined with each other without conflict. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. For example, the phrase “at least one of A, B, and C” includes within its scope “only A”, “only B”, “only C”, “A and B”, “B and C”, “A and C” and “all of A, B, and C.”

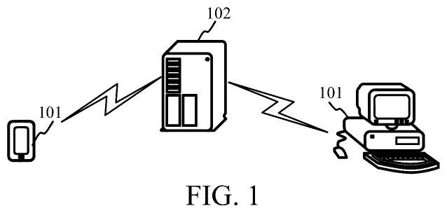

FIG. 1 is a schematic diagram of some embodiments, including a data reading method. As shown in FIG. 1, some embodiments include a terminal device 101 and a server 102. The data reading method in some embodiments may be performed by the terminal device 101, or may be performed by the server 102, or may be performed jointly by the terminal device 101 and the server 102.

The terminal device 101 may be a smartphone, a game console, a desktop computer, a tablet computer, a laptop portable computer, a smart television, a smart in-vehicle device, a smart voice interaction device, a smart home appliance, or the like. The server 102 may be one server, a server cluster formed by a plurality of servers, or any one of a cloud computing center or a virtualization center. This is not limited. The server 102 may be communicatively connected to the terminal device 101 through a wired network or a wireless network. The server 102 may have functions of data processing, data storage, data transmission and reception, and the like. This is not limited. The numbers of terminal devices 101 and servers 102 are not limited, and there may be one or more terminal devices 101 and one or more servers 102.

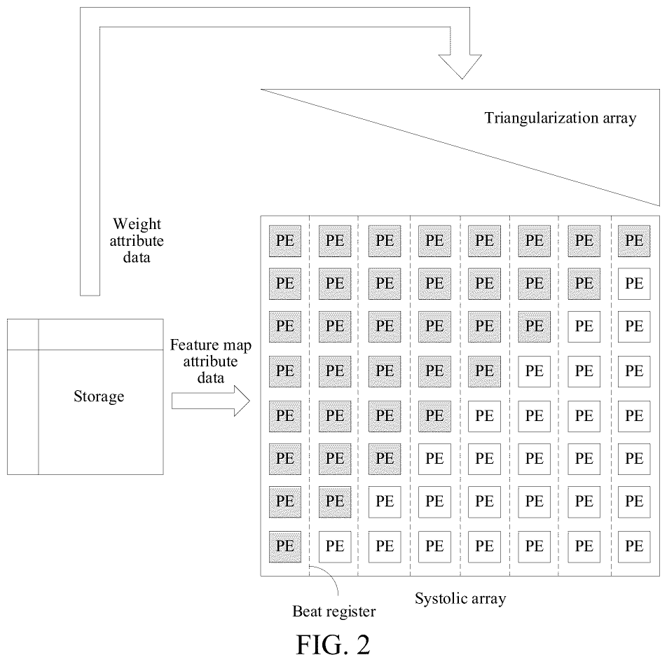

For case of understanding the following embodiments, a systolic array is described below with reference to FIG. 2. Referring to FIG. 2, FIG. 2 is a schematic diagram of data loading of a systolic array according to some embodiments.

The systolic array is an array structure, and a working manner and process of the systolic array may be similar to a working manner and process of a human blood circulation system. In the systolic array, data flows rhythmically between PEs of the systolic array in a set pipelining manner. During a data flow process, all PEs process data flowing through the PEs in parallel. The systolic array may achieve a very high parallel processing speed.

The systolic array includes M rows and N columns of PEs, and M and N are both positive integers greater than 1. In some embodiments, a beat register may be inserted between any two columns of PEs of the systolic array, and/or a beat register may be inserted between any two rows of PEs of the systolic array. Due to a large size of the systolic array, the layout and routing may be facilitated by inserting the beat register, thereby facilitating physical implementation. In addition, since the PEs may use a particular amount of time to process data, and a time for data to flow through a column of PEs is less than a time for data to flow through an entire systolic array, a clock frequency may be increased, a clock cycle may be reduced, and a delay may be reduced by inserting the beat register. In some embodiments, the beat register is a one-level beat register. For example, the systolic array shown in FIG. 2 includes eight rows and eight columns of PEs, and a beat register is inserted between each two columns of PEs of the systolic array.

An electronic device may include a processor, a storage, and a systolic array. The electronic device includes a systolic array and a storage that are connected to the processor, and the systolic array contains a weight attribute register. The electronic device may read data from the storage and load the data to the systolic array. The storage is not limited. Illustratively, the storage is any one of an L1 memory, an L2 memory, an inner disc, and the like.

Some embodiments are applicable to the technical field of artificial intelligence (AI). In the technical field of AI, processing such as feature extraction and classification may be performed on features of media information such as an image, text, and audio through a neural network model. The essence of processing the features of the media information by the neural network model is as follows: model parameters of the neural network model are calculated with the features of the media information. In some embodiments, the feature of the media information belongs to feature map attribute data, and the model parameter of the neural network model belongs to weight attribute data.

Data in the storage includes weight attribute data and feature map attribute data. When the weight attribute data and the feature map attribute data are loaded to the systolic array, there is a time sequence relationship between loading of the weight attribute data and loading of the feature map attribute data.

Taking FIG. 2 as an example, the electronic device may read the weight attribute data from the storage. The read weight attribute data may be beaten through a triangularization array, and horizontal data is converted into oblique triangular data and then input into the systolic array. Since the beat register is inserted into the systolic array, the weight attribute data may be beaten through the triangularization array.

The systolic array includes 8 rows and 8 columns of PEs. In a first clock cycle, the electronic device may load the weight attribute data from the storage based on a read request for the weight attribute data. The weight attribute data is input into the systolic array after passing through the triangularization array. The weight attribute data is located in the PE in a first row of a first column of the systolic array. In a second clock cycle, the electronic device may load the weight attribute data from the storage based on the read request for the weight attribute data. The weight attribute data is input into the systolic array after passing through the triangularization array. The weight attribute data is located in the PEs in the first row of the first column, a second row of the first column, and a first row of a second column of the systolic array. The weight attribute data loaded in the first clock cycle is located in the PE in the second row of the first column, and the weight attribute data loaded in the second clock cycle is located in the PEs in the first row of the first column and the first row of the second column. In a third clock cycle, the electronic device may load the weight attribute data from the storage based on the read request for the weight attribute data. The weight attribute data is input into the systolic array after passing through the triangularization array. The weight attribute data is located in PEs in first to third rows of the first column, first to second rows of the second column, and a first row of a third column of the systolic array. The weight attribute data loaded in the first clock cycle is located in the PE in the third row of the first column, the weight attribute data loaded in the second clock cycle is located in the PEs in the second row of the first column and the second row of the second column, and the weight attribute data loaded in the third clock cycle is located in the PEs in the first row of the first column, the first row of the second column, and the first row of the third column. The rest may be deduced by analogy.

It can be known from the foregoing descriptions of the first to the third clock cycle that, a flow manner of the weight attribute data loaded in the first clock cycle is: flowing from the PE in the first row of the first column to the PE in the second row of the first column, and then flowing to the PE in the third row of the first column. A flow manner of the weight attribute data loaded in the second clock cycle is: flowing from the PEs in the first row of the first column and the first row of the second column to the PEs in the second row of the first column and the second row of the second column. After each clock cycle, the weight attribute data already loaded to the systolic array is sunk by one row. The weight attribute data is loaded to the PE in the first row of the first column in the first clock cycle, the weight attribute data is loaded to the PEs in the first row of the first column and the first row of the second column in the second clock cycle, and the weight attribute data is loaded to the PEs in the first row of the first column, the first row of the second column, and the first row of the third column in the third clock cycle. In each clock cycle, a row of weight attribute data is newly loaded to the systolic array, and the row of weight attribute data has one more column than the weight attribute data in a previous clock cycle.

Each time after a clock cycle, the weight attribute data already loaded to the systolic array is sunk by one row. A row of weight attribute data is newly loaded to the systolic array, and the row of weight attribute data has one more column than the weight attribute data in a previous clock cycle. After eight clock cycles, the weight attribute data is located in the PEs in first to eighth rows of the first column, first to seventh rows of the second column, first to sixth rows of the third column, first to fifth rows of a fourth column, first to fourth rows of a fifth column, first to third rows of a sixth column, first to second rows of a seventh column, and a first row of an eighth column of the systolic array, such as gray PEs in FIG. 2.

The systolic array includes M rows and N columns of PEs. In a clock cycle, a row of weight attribute data is newly loaded to the systolic array, and the row of weight attribute data has one more column than the weight attribute data in a previous clock cycle. If a row of N weight attribute data is newly loaded to the systolic array in a clock cycle, a row of N weight attribute data is newly loaded to the systolic array in each clock cycle after the clock cycle. That is, weight attribute data newly loaded in one clock cycle is not greater than the number of PEs in one row.

In a case that all PEs in the first column of the systolic array are loaded with the weight attribute data, the electronic device may read the feature map attribute data from the storage. In any clock cycle, the electronic device may load the feature map attribute data from the storage based on the read request for the feature map attribute data. The feature map attribute data flows into the PEs in the first column of the systolic array from an input side (for example, a left side) of the systolic array, and the weight attribute data resident in the PEs and the feature map attribute data flowing into the PEs are calculated through the PEs in the first column. In some embodiments, at least one of a multiplication calculation and an addition calculation is performed on the weight attribute data and the feature map attribute data using the PE.

Next, one clock cycle ends, and a next clock cycle of the one clock cycle is entered. The next clock cycle of the one clock cycle is a current clock cycle at a current time. In the current clock cycle, the electronic device may load the weight attribute data from the storage based on the read request for the weight attribute data. The weight attribute data is input into the systolic array after passing through the triangularization array. The weight attribute data already loaded to the systolic array is sunk by one row, and a row of weight attribute data is newly loaded to the systolic array so that all PEs in the first column of the systolic array and all PEs in the second column of the systolic array are loaded with the weight attribute data. The feature map attribute data loaded in the previous clock cycle flows into the PEs in the second column of the systolic array, and the weight attribute data resident in the PEs and the feature map attribute data flowing into the PEs are calculated through the PEs in the second column. In the current clock cycle, the electronic device may load the feature map attribute data from the storage based on the read request for the feature map attribute data. The feature map attribute data flows into the PEs in the first column of the systolic array from the input side (for example, the left side) of the systolic array, and the weight attribute data resident in the PEs and the feature map attribute data flowing into the PEs are calculated through the PEs in the first column. The rest may be deduced by analogy.

In a case that all PEs in the first column of the systolic array are loaded with the weight attribute data, in each clock cycle, the weight attribute data already loaded to the systolic array is sunk by one row, and the feature map attribute data loaded to the systolic array is shifted right by one column. A row of weight attribute data is newly loaded to the systolic array, and a column of feature map attribute data is newly loaded to the systolic array. The feature map attribute data flowing through each PE may be calculated with the weight attribute data flowing through the PE. Finally, the weight attribute data is flowed out from a first output side (for example, a side adjacent to the input side, for example, a lower side) of the systolic array, and the feature map attribute data is flowed out from a second output side (for example, a side opposite to the input side, for example, a right side) of the systolic array.

It can be known from the foregoing content that after loading the weight attribute data in the storage to the PEs in first column of the systolic array, the electronic device may load the feature map attribute data in the storage to the PEs in first column of the systolic array, and it takes at least one clock cycle for the electronic device to load the weight attribute data in the storage to the PEs in first column of the systolic array. In addition, only in a case that the weight attribute data resident in the PEs in the first column of the systolic array and the feature map attribute data flowing into the PEs in the first column are calculated, the electronic device may load the weight attribute data in the storage to the systolic array again. Based on the foregoing content, it is known that there is a time sequence relationship between the loading of the weight attribute data and the loading of the feature map attribute data.

Only after the weight attribute data in the storage is loaded to the PEs in the first column of the systolic array after at least one clock cycle, the feature map attribute data in the storage may be loaded to the systolic array, and only after the weight attribute data in the PEs in the first column of the systolic array and the feature map attribute data flowing into the PEs in the first column are calculated, the feature map attribute data in the storage may be loaded to the systolic array again. In the related art, a queue is instantiated in the storage. When a data reading port (a port in the storage that is configured to input the feature map attribute data or the weight attribute data to the systolic array) does not have a condition for receiving data, for example, when the feature map attribute data or the weight attribute data in the storage cannot be loaded to the systolic array, data is read from the storage in response to the read request and is registered in a queue. When the data reading port has a condition for receiving data, for example, when the feature map attribute data or the weight attribute data in the storage may be loaded to the systolic array, the data is taken out from the queue and transmitted to the systolic array through the data reading port.

Since data in the storage includes the weight attribute data and the feature map attribute data, a queue corresponding to the weight attribute data and a queue corresponding to the feature map attribute data may be instantiated. Since there is a read delay, the depth of the queue may be greater than or equal to the read delay. For example, if the read delay is 10 clock cycles, the depth of the queue is at least 10. In this way, data loss may be avoided. As the amount of processing data increases, the read delay also increases so that the two queues may occupy a large amount of registering resources, resulting in a large chip area.

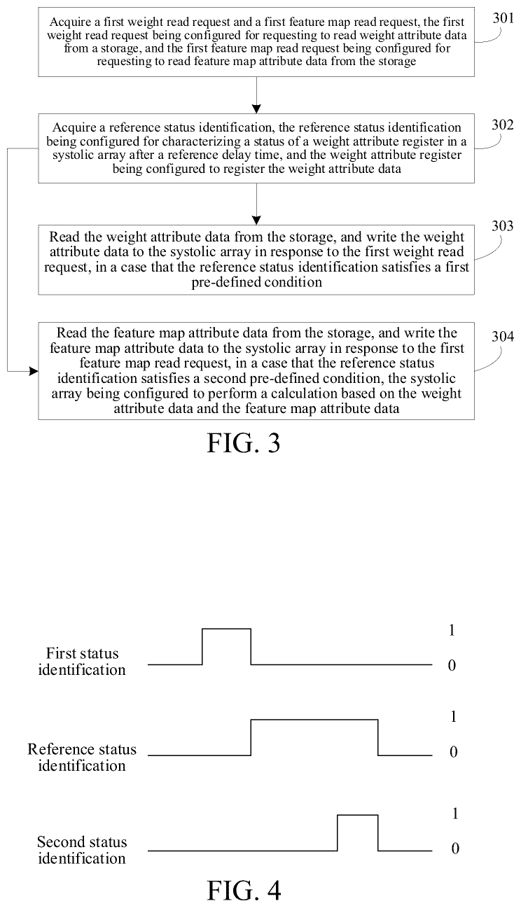

Some embodiments provide a data reading method. The method may be applied to the above-mentioned implementation environment and may reduce the chip area. Taking a flowchart of a data reading method according to some embodiments shown in FIG. 3 as an example, for the convenience of description, the terminal device 101 or the server 102 which performs the data reading method in some embodiments is referred to as an electronic device. The method may be performed by the electronic device, in particular by a processor of the electronic device. The electronic device further includes a systolic array and a storage that are connected to the processor, and the systolic array contains a weight attribute register. As shown in FIG. 3, the method includes the following operations.

Operation 301: acquire a first weight read request and a first feature map read request. The first weight read request is configured for requesting to read weight attribute data from the storage, and the first feature map read request is configured for requesting to read feature map attribute data from the storage.

The data reading method in some embodiments is applicable to the technical field of AI. In the technical field of AI, features of media information are usually processed through a neural network model. The weight attribute data belongs to a model parameter of the neural network model. In a layer of the neural network model, it may characterize the magnitude of the contribution of a variable corresponding to the weight attribute data to a calculation result of the layer. The neural network model may be a feature extraction model configured to perform feature extraction on the media information, or the neural network model may be a classification model configured to classify the media information, or the like. The feature map attribute data belongs to the features of the media information. In some embodiments, the media information includes at least one of an image, text, audio, or the like. The feature map attribute data belongs to at least one of an image feature, a text feature, an audio feature, or the like.

The electronic device may acquire the first weight read (wt_rd) request in any clock cycle, and the first weight read request is configured for reading weight attribute data. The electronic device may acquire the first feature map read (fm_rd) request in any clock cycle, and the first feature map read request is configured for reading feature map (fm) attribute data.

An order of the first weight read request and the first feature map read request is not limited. The first weight read request and the first feature map read request may be acquired at the same time, or the first weight read request may be acquired first and then the first feature map read request is acquired, or the first feature map read request may be acquired first and then the first weight read request is acquired.

Operation 302: acquire a reference status identification. The reference status identification is configured for characterizing a status of the weight attribute register in the systolic array after a pre-defined elapsed time from a current time, and the weight attribute register is configured to register the weight attribute data.

In some embodiments, the electronic device has an arbiter unit to coordinate the time sequence relationship between the weight attribute data and the feature map attribute data by maintaining a reference status register. The reference status register may be recorded as a weight occupy (wt_occupy) register and is configured to register the reference status identification. In some embodiments, the reference status identification may be recorded as wt_occupy. The reference status identification is configured for characterizing the status of the weight attribute register in the systolic array after the pre-defined elapsed time from the current time, and the weight attribute register is configured to register the weight attribute data. The pre-defined elapsed time may be a pre-defined duration calculated from a time point. In some embodiments, the pre-defined elapsed time is a time interval between a moment for determining whether the reference status identification satisfies a first pre-defined condition and a moment at which the corresponding data enters the systolic array. The time interval between the moment for determining whether the reference status identification satisfies the first pre-defined condition and the moment at which the corresponding data enters the systolic array may be the same as a time interval between a moment for determining whether the reference status identification satisfies a second pre-defined condition and a moment at which the corresponding data enters the systolic array. Since the clock frequency is regular, the pre-defined elapsed time may be preset.

Operation 303: read the weight attribute data stored in the storage to the systolic array in response to the first weight read request in a case that the reference status identification satisfies the first pre-defined condition.

When the electronic device acquires the reference status identification from the reference status register, it is equivalent to obtaining the status of the weight attribute register after the pre-defined elapsed time. The status of the weight attribute register is: the weight attribute register being in a status of waiting to register the weight attribute data, or the weight attribute register being in a status of completely registering the weight attribute data. The systolic array regularly runs according to a particular frequency. Therefore, whether the weight attribute register in the systolic array is in the status of waiting to register the weight attribute data or the status of completely registering the weight attribute data after the pre-defined elapsed time from the current time can be determined at the current time.

In some embodiments, if all PEs in the first column of the systolic array have weight attribute data, the weight attribute register is in the status of completely registering the weight attribute data. If all or some of the PEs in the first column of the systolic array do not have weight attribute data, the weight attribute register is in the status of waiting to register the weight attribute data.

In some embodiments, if the PEs in the first column of the systolic array have unused weight attribute data, the weight attribute register is in the status of completely registering the weight attribute data. If the PEs in the first column of the systolic array do not have unused weight attribute data, the weight attribute register is in the status of waiting to register the weight attribute data. If weight attribute data resident in any PE is calculated with feature map attribute data flowing through the PE, the weight attribute data has been used. If the weight attribute data resident in any PE is not calculated with the feature map attribute data flowing through the PE, the weight attribute data has not been used.

For example, if all or some of the PEs in the first column of the systolic array do not have weight attribute data, the weight attribute register is in the status of waiting to register the weight attribute data. In a case that all PEs in the first column of the systolic array have weight attribute data, if all or some of the PEs have unused weight attribute data, the weight attribute register is in the status of completely registering the weight attribute data. If all PEs have used weight attribute data, the weight attribute register is in the status of waiting to register the weight attribute data.

Whether the reference status identification satisfies the first pre-defined condition may be determined based on the status of the weight attribute register after the pre-defined elapsed time, thereby determining whether the weight attribute data may be loaded to the systolic array.

In some embodiments, in operation 303, the reference status identification satisfying the first pre-defined condition is as follows: the reference status identification characterizes that the weight attribute register is in the status of waiting to register the weight attribute data after the pre-defined elapsed time from the current time.

There are two examples that may cause the weight attribute register to be in the status of waiting to register the weight attribute data. A first case is that: all or some of the PEs in the first column of the systolic array have never received the weight attribute data. A second case is that: all PEs in the first column of the systolic array have received the weight attribute data, but the weight attribute data in all or some of the PEs is calculated with the feature map attribute data flowing through the PEs so that the weight attribute data in the PEs has been used.

In a case that all or some of the PEs in the first column of the systolic array do not have weight attribute data, and/or the weight attribute data of all PEs in the first column of the systolic array has been used, the electronic device may load the weight attribute data in the storage to the systolic array. Based on this principle, when the reference status identification characterizes that the weight attribute register is in the status of waiting to register the weight attribute data after the pre-defined elapsed time from the current time, the electronic device determines that the reference status identification satisfies the first pre-defined condition to read the weight attribute data stored in the storage to the systolic array so that all PEs in the first column of the systolic array have weight attribute data, and all or some of the PEs have unused weight attribute data.

When the reference status identification characterizes that the weight attribute register is in the status of completely registering the weight attribute data after the pre-defined elapsed time from the current time, all PEs in the first column of the systolic array have weight attribute data, and all or some of the PEs have unused weight attribute data. The electronic device cannot load the weight attribute data in the storage to the systolic array. Based on this principle, the electronic device determines that the reference status identification does not satisfy the first pre-defined condition. The electronic device may mask the first weight read request.

Operation 304: read the feature map attribute data stored in the storage to the systolic array in response to the first feature map read request in a case that the reference status identification satisfies a second pre-defined condition, the systolic array being configured to perform a calculation based on the weight attribute data and the feature map attribute data.

Operation 304 may be performed after operation 302. Whether the reference status identification satisfies the second pre-defined condition may be determined based on the status of the weight attribute register after the pre-defined elapsed time, thereby determining whether the feature map attribute data may be loaded to the systolic array.

In some embodiments, the performing calculation based on the weight attribute data and the feature map attribute data may include: determining a relationship between the weight attribute data and the feature map attribute data according to a structure of the neural network model so that the weight attribute data and the feature map attribute data are organized to participate in the calculation of the neural network model according to the relationship between the weight attribute data and the feature map attribute data to obtain a calculation result. The calculation result may be an intermediate calculation result, or may be a result finally output by the neural network model.

In some embodiments, the relationship between the weight attribute data and the feature map attribute data may be that the weight attribute data and the feature map attribute data are used as input data of a particular function in the neural network model, and output data of the function is a calculation result obtained by performing calculation based on the weight attribute data and the feature map attribute data. The relationship between the weight attribute data and the feature map attribute data may be a relationship of dot product multiplication.

In some embodiments, in operation 304, the reference status identification satisfying the second pre-defined condition is as follows: the reference status identification characterizes that the weight attribute register is in the status of completely registering the weight attribute data after the pre-defined elapsed time from the current time.

If the reference status identification characterizes that the weight attribute register is in the status of completely registering the weight attribute data after the pre-defined elapsed time from the current time, all PEs in the first column of the systolic array have weight attribute data, and all or some of the PEs have unused weight attribute data. The electronic device may load the feature map attribute data in the storage to the systolic array. Based on this principle, when the reference status identification characterizes that the weight attribute register is in the status of completely registering the weight attribute data after the pre-defined elapsed time from the current time, the electronic device determines that the reference status identification satisfies the second pre-defined condition to read the feature map attribute data stored in the storage to the systolic array so that all PEs in the first column of the systolic array may calculate the weight attribute data resident in the PEs and the feature map attribute data flowing through the PEs.

When the reference status identification characterizes that the weight attribute register is in the status of waiting to register the weight attribute data after the pre-defined elapsed time from the current time, all or some of the PEs in the first column of the systolic array do not have weight attribute data, and/or the weight attribute data of all PEs in the first column of the systolic array has been used. The electronic device cannot load the feature map attribute data in the storage to the systolic array. Based on this principle, the electronic device determines that the reference status identification does not satisfy the second pre-defined condition. The electronic device may mask the first feature map read request.

When the reference status identification satisfies the first pre-defined condition, the weight attribute data may be directly read based on the first weight read request. The first feature map read request may further be masked. When the reference status identification satisfies the second pre-defined condition, the feature map attribute data may be directly read based on the first feature map read request. The first weight read request may further be masked. Arbitration is performed on the reference status identification, facilitating construction of a time sequence between the weight attribute data and the feature map attribute data, and facilitating calculation based on the weight attribute data and the feature map attribute data through the systolic array.

In some embodiments, before operation 304, the method further includes the following operation 306 to operation 307 (FIG. 3).

Operation 306: acquire a first status identification, the first status identification characterizing whether the weight attribute register completely registers weight attribute data of a predetermined number of clock cycles after the pre-defined elapsed time from the current time.

In some embodiments, the reference status identification may be arbitrated through an arbiter unit. In a case that the reference status identification satisfies the first pre-defined condition, the weight attribute data is read based on the first weight read request; or in a case that the reference status identification does not satisfy the first pre-defined condition, the first weight read request is masked.

The arbiter unit may maintain a first status register and register the first status identification through the first status register. When a first weight read request of any clock cycle reaches the arbiter unit, if the clock cycle is a predetermined number of clock cycles, the first status identification is set to a third value, or if the clock cycle is not the predetermined number of clock cycles, the first status identification is set to a fourth value. Only a value of the first status identification in the predetermined number of clock cycles is the third value, and a value of the first status identification in other clock cycles is the fourth value. In some embodiments, the first status identification may be recorded as wt_last_beat.

When the first status identification is set from the third value to the fourth value, it characterizes that the weight attribute register completely registers the weight attribute data of the predetermined number of clock cycles after the pre-defined elapsed time from the current time. In a case that the first status identification is set from the fourth value to the third value, it characterizes that the weight attribute register starts to register the weight attribute data of the predetermined number of clock cycles after the pre-defined elapsed time from the current time.

The magnitudes of the third value and the fourth value are not limited in some embodiments. Illustratively, the third value is 1, and the fourth value is 0.

Operation 307: determine that the reference status identification characterizes that the weight attribute register is in the status of completely registering the weight attribute data after the pre-defined elapsed time from the current time in response to that the first status identification characterizes that the weight attribute register completely registers the weight attribute data of the predetermined number of clock cycles after the pre-defined elapsed time from the current time.

In a case that the first status identification is set from the third value to the fourth value, the weight attribute register completely registers the weight attribute data of the predetermined number of clock cycles after the pre-defined elapsed time, for example, the weight attribute register is in the status of completely registering the weight attribute data after the pre-defined elapsed time. The electronic device sets the reference status identification from the first value to the second value. When the reference status identification is the first value, the weight attribute register is in the status of waiting to register the weight attribute data after the pre-defined elapsed time. When the reference status identification is the second value, the weight attribute register is in the status of completely registering the weight attribute data after the pre-defined elapsed time. The magnitudes of the first value and the second value are not limited in some embodiments. Illustratively, the first value is 0, and the second value is 1.

Referring to FIG. 4, FIG. 4 is a schematic diagram of updating a status identification according to some embodiments. It can be seen from FIG. 4 that, in a case that the first status identification is set from 1 (for example, the third value) to 0 (for example, the fourth value), the reference status identification is set from 0 (for example, the first value) to 1 (for example, the second value).

In some embodiments, the method further includes operation 308 to operation 309 (FIG. 3). In some embodiments, operation 308 to operation 309 may be performed after operation 307.

Operation 308: acquire a second status identification, the second status identification characterizing whether the weight attribute data in the weight attribute register is calculated with feature map attribute data of a first clock cycle after the pre-defined elapsed time from the current time.

After the feature map read request of any clock cycle passes through the arbiter unit, in a case that the second pre-defined condition is satisfied, after the pre-defined elapsed time, feature map attribute data corresponding to the feature map read request is calculated through the systolic array and the weight attribute data registered in the weight attribute register. The arbiter unit may maintain a second status register and register the second status identification through the second status register. When a feature map read request of any clock cycle reaches the arbiter unit, if the clock cycle is a first clock cycle, the second status identification is set to a fifth value, or if the clock cycle is not the first clock cycle, the second status identification is set to a sixth value. Only a value of the second status identification in the first clock cycle is the fifth value, and a value of the second status identification in other clock cycles is the sixth value. In some embodiments, the second status identification may be recorded as fm_update_first_beat.

When the second status identification is set from the fifth value to the sixth value, it characterizes that the calculation of the weight attribute data in the weight attribute register and the feature map attribute data of the first clock cycle is completed after the pre-defined elapsed time from the current time. When the second status identification is set from the sixth value to the fifth value, it characterizes that the weight attribute data in the weight attribute register and the feature map attribute data of the first clock cycle start to be calculated.

The magnitudes of the fifth value and the sixth value are not limited. Illustratively, the fifth value is 1, and the sixth value is 0.

Operation 309: determine that the reference status identification characterizes that the weight attribute register is in the status of waiting to register the weight attribute data after the pre-defined elapsed time from the current time in a case that the second status identification characterizes that the weight attribute data in the weight attribute register is calculated with the feature map attribute data of the first clock cycle after the pre-defined elapsed time from the current time.

When the second status identification is set from the fifth value to the sixth value, the calculation of the weight attribute data in the weight attribute register and the feature map attribute data of the first clock cycle is completed after the pre-defined elapsed time. The electronic device sets the reference status identification from the second value to the first value. It can be seen from FIG. 4 that, in a case that the second status identification is set from 1 (for example, the fifth value) to 0 (for example, the sixth value), the reference status identification is set from 1 (for example, the second value) to 0 (for example, the first value).

In summary, an initial value of the reference status identification is the first value, characterizing that the weight attribute register is in the status of waiting to register the weight attribute data after the pre-defined elapsed time from the current time. The reference status identification satisfies the first pre-defined condition. The weight attribute data stored in the storage may be written to the systolic array in response to the first weight read request. If the first feature map read request is acquired, the first feature map read request is masked. This process continues for several clock cycles until the reference status identification is set from the first value to the second value.

When the reference status identification is the second value, it may characterize that the weight attribute register is in the status of completely registering the weight attribute data. The reference status identification satisfies the second pre-defined condition. Within one clock cycle, the feature map attribute data stored in the storage may be written to the systolic array in response to the first feature map read request. If the first weight read request is acquired, the first weight read request is masked. After the clock cycle, the reference status identification is set from the second value to the first value. Next, implementation A or implementation B is performed.

In implementation A, the reference status identification is the first value. In a next clock cycle, the weight attribute data stored in the storage may be written to the systolic array in response to the first weight read request, and the first feature map read request is masked. After the clock cycle, the reference status identification is set from the first value to the second value. In a next clock cycle, the feature map attribute data stored in the storage may be written to the systolic array in response to the first feature map read request, and the first weight read request is masked. After the clock cycle, the reference status identification is set from the second value to the first value. This process is repeated until reading is stopped.

In implementation B, the reference status identification is the first value. Next, operation 310 to operation 311 (FIG. 3) are performed. Operation 310 to operation 311 may be performed after operation 304 or after “the reference status identification is set from the second value to the first value”.

Operation 310: acquire a second weight read request and a second feature map read request, the second weight read request being configured for requesting to read the weight attribute data from the storage, and the second feature map read request being configured for requesting to read the feature map attribute data from the storage.

The electronic device may further acquire the second weight read request in any clock cycle, and the second weight read request is configured for reading the wt attribute data. The electronic device may further acquire the second feature map read request in any clock cycle, and the second feature map read request is configured for reading the fm attribute data. The electronic device may acquire the second weight read request and the second feature map read request at the same time, or first acquire the second weight read request and then acquire the second feature map read request, or first acquire the second feature map read request and then acquire the second weight read request.

Operation 311: read the weight attribute data stored in the storage to the systolic array based on the second weight read request, and read the feature map attribute data stored in the storage to the systolic array based on the second feature map read request, a read delay of the weight attribute data and a read delay of the feature map attribute data each being the pre-defined elapsed time.

The read delay of the weight attribute data and the read delay of the feature map attribute data each are the pre-defined elapsed time, for example, the read delay of the weight attribute data is equal to the read delay of the feature map attribute data. Each time the weight attribute data of one clock cycle is loaded to the systolic array, correspondingly, the feature map attribute data of one clock cycle flows into the systolic array and is calculated with the weight attribute data resident in the systolic array so that the time sequence relationship between the weight attribute data and the feature map attribute data is maintained. The weight attribute data stored in the storage may be directly written to the systolic array based on the second weight read request, and the feature map attribute data stored in the storage may be written to the systolic array based on the second feature map read request without determining whether the reference status identification satisfies the first pre-defined condition or the second pre-defined condition.

In a case that the read delay of the weight attribute data is equal to the read delay of the feature map attribute data, the time sequence relationship between the weight attribute data and the feature map attribute data may be maintained. A queue may not be introduced to register data, which reduces registering resources used by the queue and facilitates reducing the chip area. The corresponding data is directly read based on the second weight read request or the second feature map read request without determining whether the reference status identification satisfies the first pre-defined condition or the second pre-defined condition so that efficient switching between the weight read request and the feature map read request may be realized, data reading efficiency is sped up, and an operation time is reduced.

In some embodiments, the first weight read request includes at least one first weight sub-request, and the storage includes at least one first storage block. For example, the first weight read request includes four first weight sub-requests, which are recorded as req0 to req3, respectively, and the storage includes four first storage blocks, which are marked as bg0 to bg3, respectively.

In operation 303, “reading the weight attribute data stored in the storage to the systolic array in response to the first weight read request” includes operation 3031 to operation 3032 (FIG. 3) shown below.

Operation 3031: determine, for any first weight sub-request, a first storage block corresponding to the any first weight sub-request in a case that the any first weight sub-request is a valid request, and read weight attribute data corresponding to the any first weight sub-request from the first storage block corresponding to the any first weight sub-request.

The electronic device may directly determine any first weight sub-request as a valid request, or may compare any first weight sub-request with a reference first weight sub-request, and determine whether the any first weight sub-request is a valid request according to a comparison result.

In some embodiments, “determining that the any first weight sub-request is a valid request” in operation 3031 includes: extracting an address (Addr) of the first storage block corresponding to the any first weight sub-request from the any first weight sub-request; and determining that the any first weight sub-request is a valid request in response to the address of the first storage block corresponding to the any first weight sub-request being different from an address of a first storage block corresponding to a reference first weight sub-request, the reference first weight sub-request being at least one first weight sub-request except the any first weight sub-request in a plurality of first weight sub-requests.

Any first weight sub-request includes an identification bit and an address. The identification bit is configured for characterizing that the first weight sub-request is a valid request, and the address is a storage address of data corresponding to the first weight sub-request.

In some embodiments, data corresponding to any first weight sub-request may be read from the storage. Since the storage includes at least one first storage block, any first weight sub-request includes the address of the first storage block to read the weight attribute data corresponding to the first weight sub-request from the first storage block.

Any first weight sub-request corresponds to an address of a first storage block, and any two first weight sub-requests may correspond to an address of the same first storage block or may correspond to addresses of different first storage blocks. Based on this, whether two first weight sub-requests correspond to the address of the same first storage block may be determined.

In some embodiments, since any first weight sub-request includes the address of the first storage block, the address corresponding to the first storage block may be extracted from the first weight sub-request. The address of the first storage block corresponding to the any first weight sub-request is compared with an address of a first storage block corresponding to the reference first weight sub-request. If a comparison result is that the two addresses are different, it is determined that any first weight sub-request is a valid request; or if a comparison result is that the two addresses are the same, it is determined that any first weight sub-request is an invalid request.

There is at least one reference first weight sub-request. In a case that there are at least two reference first weight sub-requests, if the address of the first storage block corresponding to the any first weight sub-request is different from addresses of first storage blocks corresponding to the reference first weight sub-requests, it is determined that the any first weight sub-request is an invalid request. If the address of the first storage block corresponding to the reference first weight sub-request is the same as the address of the first storage block corresponding to any first weight sub-request, it is determined that the any first weight sub-request is an invalid request.

The manner for determining the reference first weight sub-request is not limited. In some embodiments, each first weight sub-request except the any first weight sub-request in the plurality of first weight sub-requests may be used as the reference first weight sub-request, or each first weight sub-request located before (or after) the any first weight sub-request in the plurality of first weight sub-requests may be used as the reference first weight sub-request.

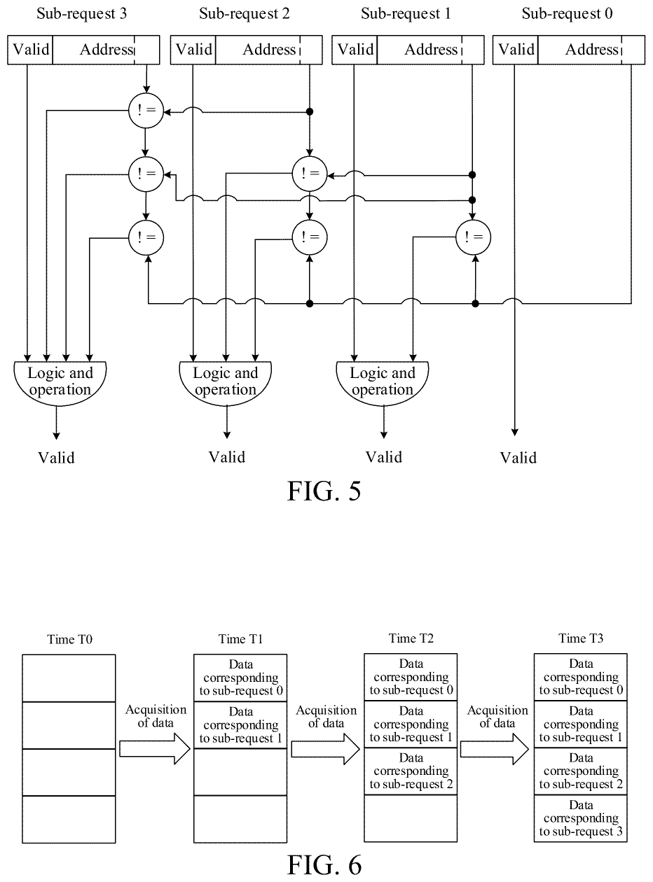

Referring to FIG. 5, FIG. 5 is a schematic diagram of determining whether a sub-request is valid according to some embodiments. In some embodiments, the first weight read request includes four first weight sub-requests, which are recorded as a sub-request 0 to a sub-request 3, respectively. For any first weight sub-request, the first weight sub-request includes an identification bit configured for characterizing that the first weight sub-request is valid and an address configured for storing data corresponding to the first weight sub-request. All or some of addresses included in any first weight sub-request are addresses of the first storage block. For example, FIG. 5 shows that the sub-request 0 to the sub-request 3 each include an identification bit characterizing “valid” and an address, and a part of the address is the address corresponding to the first storage block.

For the sub-request 0, the electronic device may directly determine whether the sub-request 0 is valid. For example, the electronic device directly determines that the sub-request 0 is a valid request.

For the sub-request 1, the electronic device may compare an address of the first storage block corresponding to the sub-request 0 with an address of the first storage block corresponding to the sub-request 1, and in a case that a comparison result shows that the two addresses are different (where “!=” is an operation symbol in the computer and characterizes that the two variables are not equal), and the identification bit of the sub-request 1 characterizes “valid”, a logic and operation is performed on the comparison result and the identification bit to obtain that the sub-request 1 is valid. For the logic and operation, an operation result is determined to be true when two operands are both true. In some embodiments, when the comparison result shows that the two addresses are different, the operand corresponding to the comparison result characterizes that the sub-request 1 is “valid”, which is equivalent to true. The identification bit of the sub-request 1 characterizes that the sub-request 1 is “valid”, which is equivalent to true. The operation result is true, for example, the operation result is that the sub-request 1 is “valid”.

In a case that the comparison result shows that the two addresses are the same, and the identification bit of the sub-request 1 characterizes that the sub-request 1 is “valid”, a logic and operation is performed on the comparison result and the identification bit to obtain that the sub-request 1 is invalid. When the comparison result shows that the two addresses are the same, an operand corresponding to the comparison result characterizes that the sub-request 1 is “invalid”.

For the sub-request 2, based on a principle similar to that of the sub-request 1, an address of the first storage block corresponding to the sub-request 2 may be compared with addresses of the first storage blocks corresponding to the sub-requests 0 and 1, and in a case that a comparison result shows that the addresses are different, and the identification bit of the sub-request 2 characterizes “valid”, a logic and operation is performed on the comparison result and the identification bit to obtain that the sub-request 2 is valid. In a case that the comparison result shows that the addresses are the same, and the identification bit of the sub-request 2 characterizes that the sub-request 2 is “valid”, a logic and operation is performed on the comparison result and the identification bit to obtain that the sub-request 2 is invalid.

For the sub-request 3, based on a principle similar to that of the sub-request 1, an address of the first storage block corresponding to the sub-request 3 may be compared with addresses of the first storage blocks corresponding to the sub-requests 0, 1, and 2, and in a case that a comparison result shows that the addresses are different, and the identification bit of the sub-request 3 characterizes “valid”, a logic and operation is performed on the comparison result and the identification bit to obtain that the sub-request 3 is valid. In a case that the comparison result shows that the addresses are the same, and the identification bit of the sub-request 3 characterizes that the sub-request 3 is “valid”, a logic and operation is performed on the comparison result and the identification bit to obtain that the sub-request 3 is invalid.

In some embodiments, for any first weight sub-request, in a case that the identification bit of the first weight sub-request is a seventh value, it is determined that the identification bit of the first weight sub-request characterizes “valid”. In a case that the identification bit of the first weight sub-request is an eighth value, it is determined that the identification bit of the first weight sub-request characterizes “invalid”. The seventh value and the eighth value are not limited. In some embodiments, the seventh value is 1, and the eighth value is 0.

Since any first weight sub-request includes the address of the first storage block, the first storage block corresponding to the first weight sub-request may be determined based on the address of the first storage block included in the any first weight sub-request, and the data corresponding to the first weight sub-request may be read from the first storage block.

In some embodiments, any first storage block includes at least one second storage block. For example, a first storage block 0 includes second storage blocks 0 and 1, a first storage block 1 includes second storage blocks 0 and 1, a first storage block 2 includes second storage blocks 0 and 1, and a first storage block 3 includes second storage blocks 0 and 1. Since the first storage block includes at least one second storage block, the second storage block may be recorded as a bank, and the first storage block may be recorded as a bank group.

“Reading weight attribute data corresponding to the any first weight sub-request from the first storage block corresponding to the any first weight sub-request” in operation 3031 includes: determining a second storage block corresponding to the any first weight sub-request based on the any first weight sub-request; and reading the weight attribute data corresponding to the any first weight sub-request from the second storage block corresponding to the any first weight sub-request.

Since the any first weight sub-request includes the address of the first storage block, and the first storage block includes at least one second storage block, the any first weight sub-request may include an address of the second storage block. The second storage block corresponding to the any first weight sub-request may be determined based on the address of the second storage block included in the any first weight sub-request, and the weight attribute data corresponding to the first weight sub-request is read from the second storage block.

Operation 3032: transmit weight attribute data corresponding to first weight sub-requests to the systolic array.

Since the electronic device may determine whether the first weight sub-requests in the first weight read request are valid requests, and only in a case that the first weight sub-requests are valid requests, the data corresponding to the first weight sub-requests may be read, there is a difference in read completion times of the data corresponding to the first weight sub-requests. The data corresponding to the first weight sub-requests may be acquired through an acquisition unit. After acquiring the data corresponding to the first weight sub-requests, the acquisition unit exports the data corresponding to the first weight sub-requests as the weight attribute data corresponding to the first weight read request from the storage according to an exporting command (for example, a reg command), thereby transmitting the weight attribute data to the systolic array.

Referring to FIG. 6, FIG. 6 is a schematic diagram of a data acquisition process according to some embodiments. In some embodiments, the first weight read request includes four first weight sub-requests, which are sub-requests 0 to 3, respectively. At the time T0, the acquisition unit has not acquired data corresponding to the any first weight sub-request. At the time T1, the acquisition unit has acquired data corresponding to sub-requests 0 and 1. At the time T2, the acquisition unit has acquired data corresponding to sub-requests 0 to 2. At the time T3, the acquisition unit has acquired data corresponding to sub-requests 0 to 3. According to the export command, the data corresponding to the sub-requests 0 to 3 is exported from the storage as the weight attribute data corresponding to the first weight read request.

The first feature map read request includes at least one first feature map sub-request, the second weight read request includes at least one second weight sub-request, and the second feature map read request includes at least one second feature map sub-request. Implementations of “reading the feature map attribute data stored in the storage to the systolic array in response to the first feature map read request”, “reading the weight attribute data stored in the storage to the systolic array based on the second weight read request”, and “reading the feature map attribute data stored in the storage to the systolic array based on the second feature map read request” may refer to the foregoing descriptions of operation 3031 to operation 3032.

In some embodiments, the method further includes operation 312 to operation 313 (FIG. 3).

Operation 312: acquire a write request.

The electronic device may acquire the write request in any clock cycle. The write request is configured for writing the weight attribute data or the feature map attribute data into the storage. The write request may be a direct memory access (DMA)-based data migration write (wr) request and is configured for migrating data from other memories to the storage. The write request may be recorded as a dma_wr request.

Operation 313: write corresponding weight attribute data or feature map attribute data into the storage based on the write request.

In some embodiments, the write request includes at least one third sub-request, and the storage includes at least one first storage block. For example, the write request includes four third sub-requests, and the storage includes four first storage blocks.

In this case, operation 313 includes: determining, for any third sub-request, a first storage block corresponding to the any third sub-request; and writing data corresponding to the any third sub-request into the first storage block corresponding to the any third sub-request based on the any third sub-request.

In some embodiments, any third sub-request includes the address of the first storage block. The first storage block corresponding to the third sub-request may be determined based on the address of the first storage block included in the any third sub-request, and the weight attribute data or the feature map attribute data corresponding to the third sub-request is written into the first storage block corresponding to the third sub-request.

In some embodiments, any first storage block includes at least one second storage block. In this case, “writing data corresponding to the any third sub-request into the first storage block corresponding to the any third sub-request based on the any third sub-request” includes: determining a second storage block corresponding to the any third sub-request based on the any third sub-request; and writing the data corresponding to the any third sub-request into the second storage block corresponding to the any third sub-request.

Since any third sub-request includes the address of the first storage block, and the first storage block includes at least one second storage block, any third sub-request may include an address of the second storage block. The second storage block corresponding to the third sub-request may be determined based on the address of the second storage block included in the any third sub-request, and the data corresponding to the third sub-request is written into the second storage block corresponding to the third sub-request.

Since the electronic device may receive the write request, the feature map read request, and the weight read request, priorities of various requests may be coordinated through a scheduler. In some embodiments, the scheduler is a strict priority (SP) scheduler.

Since the weight attribute data and the feature map attribute data have a particular time sequence relationship, after the weight attribute data is loaded to the PEs in the first column of the systolic array, the feature map attribute data may be first loaded to the systolic array so that the weight attribute data may be loaded to the systolic array again after calculating the feature map attribute data flowing through the systolic array and the weight attribute data resident in the systolic array. Based on the foregoing content, a priority of a (first or second) weight read request is lower than a priority of a (first or second) feature map read request. A priority of the write request may be higher or lower than the priority of the weight read request, or may be higher or lower than the priority of the feature map read request. Illustratively, the priority of the feature map read request is higher than the priority of the weight read request, and the priority of the weight read request is higher than the priority of the write request.

The priorities of various requests are coordinated through the scheduler so that data can be read and written orderly, thereby realizing efficient switching among multiple requests, and improving data processing efficiency.

The information (including, but not limited to, user device information, user personal information, and the like), data (including, but not limited to, data for analysis, stored data, displayed data, and the like), and signals involved in some embodiments all are authorized by the user or fully authorized by each party, and the acquisition, use, and processing of relevant data should comply with relevant laws and regulations of relevant regions. For example, first data, second data, third data, referred to in some embodiments are all acquired under full authorization.

In the foregoing method, the status of the weight attribute register in the systolic array is characterized through the reference status identification. The weight attribute data stored in the storage is written to the systolic array in response to the first weight read request in a case that the reference status identification satisfies the first pre-defined condition. The feature map attribute data stored in the storage is written to the systolic array in response to the first feature map read request in a case that the reference status identification satisfies the second pre-defined condition. The reference status identification may use fewer registering resources relative to the registering resources used by the queue. The method may be applied to a chip. The fewer the registering resources, the smaller the chip area. The chip is provided with a condition of reducing the chip area.

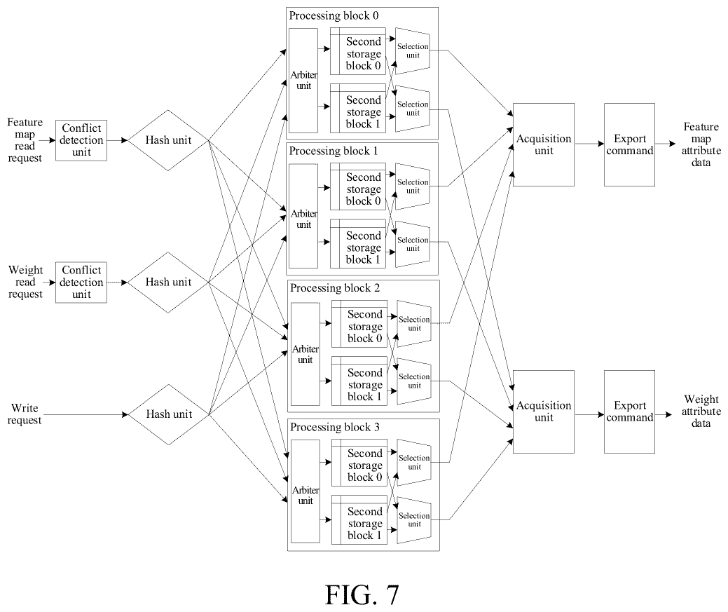

The foregoing describes the data reading method according to some embodiments from a perspective of operations of the method. The following is a systematic and comprehensive description. Referring to FIG. 7, FIG. 7 is an architectural diagram of a storage system according to some embodiments. The storage system includes conflict detection units, hash units, at least one processing block, and acquisition units, and any processing block includes an arbiter unit, at least one second storage block, and selection units.

In some embodiments, one first storage block includes second storage blocks in one processing block, for example, one processing block corresponds to one first storage block, and the storage includes the first storage blocks. As shown in FIG. 7, the storage includes a first storage block corresponding to a processing block 0, a first storage block corresponding to a processing block 1, a first storage block corresponding to a processing block 2, and a first storage block corresponding to a processing block 3. The first storage block corresponding to the processing block 0 includes second storage blocks 0 and 1 in the processing block 0. The first storage block corresponding to the processing block 1 includes second storage blocks 0 and 1 in the processing block 1. The first storage block corresponding to the processing block 2 includes second storage blocks 0 and 1 in the processing block 2. The first storage block corresponding to the processing block 3 includes second storage blocks 0 and 1 in the processing block 3.

In some embodiments, the electronic device may read the feature map attribute data from the storage based on the feature map read request, or may read the weight attribute data from the storage based on the weight read request. In some embodiments, a manner for processing the feature map read request is similar to a manner for processing the weight read request. Therefore, taking the feature map read request as an example, the manner for processing the feature map read request in some embodiments is described below.

After acquiring the feature map read request (corresponding to the first feature map read request and the second feature map read request), the electronic device performs conflict detection on the feature map read request through the conflict detection unit. A principle of the conflict detection is shown in FIG. 5. In some embodiments, the feature map read request includes a sub-request 0 to a sub-request 3. For the sub-request 0, it is directly determined that the sub-request 0 is valid. For the sub-request 1, it is determined that the sub-request 1 is valid when an address of a first storage block corresponding to the sub-request 0 is different from an address of a first storage block corresponding to the sub-request 1. It is determined that the sub-request 1 is invalid. For the sub-request 2, it is determined that the sub-request 2 is valid when the addresses of the first storage blocks corresponding to the sub-requests 0 and 1 are different from an address of a first storage block corresponding to the sub-request 2. It is determined that the sub-request 2 is invalid. For the sub-request 3, it is determined that the sub-request 3 is valid when the addresses of the first storage blocks corresponding to the sub-requests 0 to 2 are different from an address of a first storage block corresponding to the sub-request 3. It is determined that the sub-request 3 is invalid.

After conflict detection is performed on the feature map read request, whether the sub-requests included in the feature map read request are valid may be determined. For any sub-request, if the sub-request is valid, a first storage block corresponding to the sub-request is determined based on an address of the first storage block corresponding to the sub-request through the hash unit, and a request path of a processing block where the first storage block corresponding to the sub-request is located is set to be valid so that the sub-request can reach the corresponding first storage block. If the sub-request is invalid, the request path of the processing block where the first storage block corresponding to the sub-request is located is set to be invalid through the hash unit to prevent the sub-request from reaching the corresponding first storage block.

For example, the sub-request 0 corresponds to a first storage block 0, and the processing block 0 includes the first storage block 0. If the sub-request 0 is valid, a request path of the processing block 0 is set to be valid through the hash unit so that the sub-request 0 reaches the first storage block 0. If the sub-request 0 is invalid, the request path of the processing block 0 is set to be invalid through the hash unit to prevent the sub-request 0 from reaching the first storage block 0.

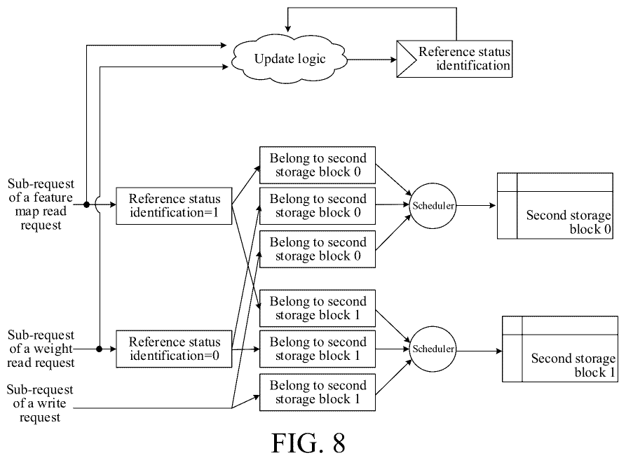

In some embodiments, the storage system includes at least one processing block, one processing block includes an arbiter unit, a first storage block, and selection units, and the first storage block includes at least one second storage block. A schematic structural diagram of the arbiter unit may refer to FIG. 8.

For any sub-request of the feature map read request, after the sub-request is input into a corresponding processing block, the sub-request is first arbitrated through the arbiter unit. As shown in FIG. 8, the arbiter unit is configured with an update logic of the reference status identification, and the update logic is shown in FIG. 4.

Initial values of the reference status identification, the first status identification, and the second status identification are all 0. In the first clock cycle, the electronic device may read the weight attribute data from the storage and load the weight attribute data to the weight attribute register of the systolic array after the pre-defined elapsed time. If the weight attribute register is in the status of waiting to register the weight attribute data after the pre-defined elapsed time, in the second clock cycle, the electronic device may further read the weight attribute data from the storage and load the weight attribute data to the weight attribute register of the systolic array after the pre-defined elapsed time. This loading manner continues for several clock cycles until the weight attribute register is in the status of completely registering the weight attribute data after the pre-defined elapsed time. The clock cycle may be recorded as a predetermined number of clock cycles. In the predetermined number of clock cycles, the electronic device reads the weight attribute data from the storage and loads the weight attribute data to the weight attribute register of the systolic array after the pre-defined elapsed time. The weight attribute register is in the status of completely registering the weight attribute data.

When a sub-request of a weight read request corresponding to the predetermined number of clock cycles flows into the arbiter unit, the first status identification may be set from 0 to 1. When the sub-request flows out of the arbiter unit, the first status identification may be set from 1 to 0. When the first status identification is set from 1 to 0, it may indicate that after the pre-defined elapsed time, the weight attribute register completely registers the weight attribute data of the predetermined number of clock cycles. The reference status identification is set from 0 to 1.

When the weight attribute register completely registers the weight attribute data of the predetermined number of clock cycles, it is equivalent to that the weight attribute register is in the status of completely registering the weight attribute data. The electronic device may read the feature map attribute data from the storage in any clock cycle. After the pre-defined elapsed time, the feature map attribute data flows into the systolic array and is calculated with the weight attribute data in the weight attribute register. The clock cycle is a first clock cycle for reading the feature map attribute data.

When a sub-request of a feature map read request corresponding to the first clock cycle flows into the arbiter unit, the second status identification may be set from 0 to 1. When the sub-request flows out of the arbiter unit, the second status identification may be set from 1 to 0. When the second status identification is set from 1 to 0, it may indicate that the weight attribute data of the weight attribute register is calculated with the feature map attribute data of the first clock cycle after the pre-defined elapsed time. The reference status identification is set from 1 to 0.

In summary, it can be learned that the reference status identification is first set from 0 to 1, and then is set from 1 to 0. When any sub-request of the feature map read request is arbitrated through the arbiter unit, the reference status identification may be acquired. If the reference status identification is equal to 1, it is determined that the sub-request satisfies the second pre-defined condition, the second storage block to which the sub-request belongs is determined based on the address carried by the sub-request, and the sub-request is transmitted to the corresponding second storage block through the scheduler. If the reference status identification is equal to 0, it is determined that the sub-request does not satisfy the second pre-defined condition, and the sub-request is masked. For example, if the sub-request satisfies the second pre-defined condition and the sub-request belongs to the second storage block 0, the sub-request is transmitted to the second storage block 0 through the scheduler. If the sub-request satisfies the second pre-defined condition and the sub-request belongs to the second storage block 1, the sub-request is transmitted to the second storage block 1 through the scheduler.

Next, data corresponding to the sub-request is read from the second storage block corresponding to the sub-request through the selection unit based on any sub-request of the feature map read request. The data corresponding to the sub-requests is acquired through the acquisition unit. The acquisition process may refer to the description in FIG. 6. After the acquisition unit acquires the data corresponding to the sub-requests of the feature map read request, it is equivalent to that the feature map attribute data corresponding to the feature map read request is acquired. The feature map attribute data is input into the systolic array through the export command.

When the sub-requests of the feature map read request of one clock cycle are arbitrated through the arbiter unit, arbitration results of the sub-requests are the same. After the feature map read request of one clock cycle is arbitrated through the arbiter unit, the feature map read request may be input to the conflict detection unit for the foregoing processing. The sub-requests of the feature map read request may be arbitrated through the arbiter unit in the processing block, or the processing block may not include the arbiter unit. The sub-requests of the feature map read request may be directly transmitted to a corresponding second storage block through the hash unit, or the sub-requests of the feature map read request may be directly transmitted to a corresponding scheduler through the hash unit and transmitted to the corresponding second storage block after being scheduled by the scheduler.

Similar processing may be performed on the weight read request according to the above-mentioned manner for processing the feature map read request. When any sub-request of the weight read request is arbitrated through the arbiter unit, if the reference status identification is equal to 0, it is determined that the sub-request satisfies the first pre-defined condition, a second storage block to which the sub-request belongs is determined based on an address carried by the sub-request, and the sub-request is transmitted to the corresponding second storage block through the scheduler. If the reference status identification is equal to 1, it is determined that the sub-request does not satisfy the first pre-defined condition, and the sub-request is masked.

The sub-request of the weight read request (corresponding to the first weight read request) is determined to satisfy the first pre-defined condition in each of several clock cycles through the arbiter unit. As time passes, when it is determined through the arbiter unit that the sub-request of the weight read request does not satisfy the first pre-defined condition, the sub-request of the feature map read request (corresponding to the first feature map read request) may be determined to satisfy the second pre-defined condition through the arbiter unit. Once the sub-request of the feature map read request is determined to satisfy the second pre-defined condition through the arbiter unit, in a case that the read delay of the weight attribute data is the same as the read delay of the feature map attribute data, subsequent reading of the weight attribute data and reading of the feature map attribute data may not be arbitrated through the arbiter unit. The sub-request of the subsequent weight read request (corresponding to the second weight read request) and the sub-request of the feature map read request (corresponding to the second feature map read request) may not be arbitrated through the arbiter unit. This is because the read delay of the weight attribute data and the read delay of the feature map attribute data are both reference time cycles. Each time the weight attribute data of one clock cycle is loaded to the systolic array, correspondingly, the feature map attribute data of one clock cycle flows into the systolic array and is calculated with the weight attribute data resident in the systolic array so that the time sequence relationship between the weight attribute data and the feature map attribute data is maintained. Arbitration of the arbiter unit may not be performed.

In some embodiments, the electronic device may write the feature map attribute data and the weight attribute data into the storage based on the write request. A manner for processing the write request is described below.

The write request includes at least one sub-request (corresponding to the third sub-request). For any sub-request, a first storage block corresponding to the sub-request is determined based on an address of the first storage block corresponding to the sub-request through the hash unit, and a request path of a processing block where the first storage block corresponding to the sub-request is located is set to be valid so that the sub-request can reach the corresponding first storage block. If the sub-request is invalid, the request path of the processing block where the first storage block corresponding to the sub-request is located is set to be invalid through the hash unit to prevent the sub-request from reaching the corresponding first storage block. The second storage block to which the sub-request belongs may be determined based on the address carried by the sub-request, and the sub-request is transmitted to the corresponding second storage block through the scheduler to write the data corresponding to the sub-request into the second storage block.

Since the scheduler may receive the sub-request of the feature map read request, the sub-request of the weight read request, and the sub-request of the write request, priorities of various sub-requests may be configured. In some embodiments, a priority of the sub-request of the feature map read request is higher than a priority of the sub-request of the weight read request, and the priority of the sub-request of the weight read request is higher than a priority of the sub-request of the write request. The scheduler transmits various sub-requests to the second storage block orderly based on the priorities of various sub-requests.

In some embodiments, whether the sub-request of the feature map read request satisfies the second pre-defined condition or whether the sub-request of the weight read request satisfies the first pre-defined condition is determined through the arbiter unit based on the reference status identification. When the condition is satisfied, the data corresponding to the sub-request is read from the second storage block. The reference status identification may use fewer registering resources relative to the registering resources used by the queue, which facilitates reducing the chip area.

For example, for a memory access system with a read delay of 6 and a read data width of 2 kilo-bit (kb), in the related art, two queues with a depth of 6 and a width of 2 kb may be set. One queue is configured to register the weight attribute data, the other queue is configured to register the feature map attribute data, and the two queues may consume registers of 24 kb. Compared with the chip area in the related art, the chip area in some embodiments may be reduced by 29491.2 square microns (um2).

When the sub-request of the weight read request satisfies the first pre-defined condition or the sub-request of the feature map read request satisfies the second pre-defined condition, corresponding data may be directly read, and when the sub-request does not satisfy a condition, the sub-request is masked. The sub-request is arbitrated through the arbiter unit, thereby facilitating the construction of the time sequence between the weight attribute data and the feature map attribute data. Once the sub-request of the feature map read request is determined to satisfy the second pre-defined condition through the arbiter unit, in a case that the read delay of the weight attribute data is the same as the read delay of the feature map attribute data, subsequent reading of the weight attribute data and reading of the feature map attribute data may not be arbitrated through the arbiter unit, the corresponding data is read directly, and the time sequence between the weight attribute data and the feature map attribute data can also be maintained. Based on the foregoing content, in some embodiments, efficient switching among multiple requests can be realized, which facilitates improving the data reading efficiency.

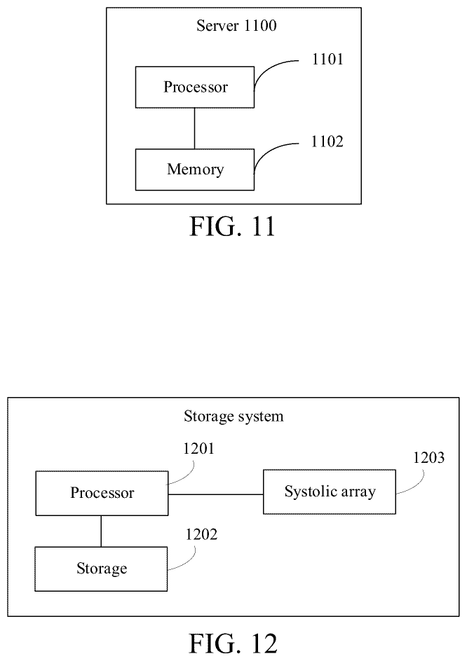

Referring to FIG. 12, FIG. 12 is an architectural diagram of another storage system according to some embodiments. The storage system includes a processor 1201 and further includes a storage 1202 and a systolic array 1203 that are connected to the processor 1201.

The storage 1202 is configured to store weight attribute data and feature map attribute data.

The processor 1201 is configured to acquire a first weight read request and a first feature map read request, the first weight read request is configured for requesting to read the weight attribute data from the storage, and the first feature map read request is configured for requesting to read the feature map attribute data from the storage.

The processor 1201 is further configured to acquire a reference status identification, the reference status identification is configured for characterizing a status of a weight attribute register in the systolic array 1203 after a pre-defined elapsed time from a current time, and the weight attribute register is configured to register the weight attribute data.

The processor 1201 is further configured to read the weight attribute data stored in the storage to the systolic array 1203 in response to the first weight read request in a case that the reference status identification satisfies a first pre-defined condition.

The processor 1201 is further configured to read the feature map attribute data stored in the storage to the systolic array 1203 in response to the first feature map read request in a case that the reference status identification satisfies a second pre-defined condition.

The systolic array 1203 is configured to perform a calculation based on the weight attribute data and the feature map attribute data.

In some embodiments, the processor 1201 includes a first status register, a reference status register, and a determining unit.

The first status register is configured to register a first status identification, and the first status identification characterizes whether the weight attribute register completely registers weight attribute data of a predetermined number of clock cycles after the pre-defined elapsed time from the current time

The reference status register is configured to register the reference status identification.

The determining unit is configured to acquire the first status identification; and determine that the reference status identification characterizes that the weight attribute register is in a status of completely registering the weight attribute data after the pre-defined elapsed time from the current time in a case that the first status identification characterizes that the weight attribute register completely registers the weight attribute data of the predetermined number of clock cycles after the pre-defined elapsed time from the current time; the reference status identification satisfying a second pre-defined condition is as follows: the reference status identification characterizes that the weight attribute register is in the status of completely registering the weight attribute data after the pre-defined elapsed time from the current time.

In some embodiments, the processor 1201 includes a second status register, a reference status register, and a determining unit.

The second status register is configured to register a second status identification, and the second status identification characterizes whether the weight attribute data in the weight attribute register is calculated with feature map attribute data of a first clock cycle after the pre-defined elapsed time from the current time.

The reference status register is configured to register the reference status identification.

The determining unit is configured to acquire the second status identification; and determine that the reference status identification characterizes that the weight attribute register is in a status of waiting to register the weight attribute data after the pre-defined elapsed time from the current time in a case that the second status identification characterizes that the weight attribute data in the weight attribute register is calculated with the feature map attribute data of the first clock cycle after the pre-defined elapsed time from the current time; the reference status identification satisfying a first pre-defined condition is as follows: the reference status identification characterizes that the weight attribute register is in the status of waiting to register the weight attribute data after the pre-defined elapsed time from the current time.

In some embodiments, the processor 1201 is further configured to acquire a second weight read request and a second feature map read request, the second weight read request is configured for requesting to read the weight attribute data from the storage, and the second feature map read request is configured for requesting to read the feature map attribute data from the storage.

The processor 1201 is further configured to read the weight attribute data stored in the storage to the systolic array 1203 based on the second weight read request.

The processor 1201 is further configured to read the feature map attribute data stored in the storage to the systolic array 1203 based on the second feature map read request, a read delay of the weight attribute data and a read delay of the feature map attribute data each being the pre-defined elapsed time.

In some embodiments, the processor 1201 includes a hash unit, a reading unit, and an acquisition unit, and the storage 1202 includes at least one first storage block.

Any first storage block is configured to store the weight attribute data and the feature map attribute data.

The hash unit is configured to determine, for any first weight sub-request, a first storage block corresponding to the any first weight sub-request in a case that the any first weight sub-request is a valid request, and the first weight read request includes at least one first weight sub-request.

The reading unit is configured to read weight attribute data corresponding to the any first weight sub-request from the first storage block corresponding to the any first weight sub-request.

The acquisition unit is configured to acquire weight attribute data corresponding to first weight sub-requests and transmit the weight attribute data corresponding to the first weight sub-requests to the systolic array 1203.

In some embodiments, the system further includes a conflict detection unit.

The conflict detection unit is configured to extract an address of the first storage block corresponding to the any first weight sub-request from the any first weight sub-request.

The conflict detection unit is further configured to determine that the any first weight sub-request is a valid request when the address of the first storage block corresponding to the any first weight sub-request is different from an address of a first storage block corresponding to a reference first weight sub-request, and the reference first weight sub-request is at least one first weight sub-request except the any first weight sub-request in a plurality of first weight sub-requests.

In some embodiments, any first storage block includes at least one second storage block.

Any second storage block is configured to store the weight attribute data and the feature map attribute data.

The reading unit is configured to determine a second storage block corresponding to the any first weight sub-request; and read the weight attribute data corresponding to the any first weight sub-request from the second storage block corresponding to the any first weight sub-request.

In some embodiments, the processor 1201 is further configured to acquire a write request, the write request being configured for writing the weight attribute data or the feature map attribute data into the storage; and write weight attribute data or feature map attribute data corresponding to the write request into the storage.

In some embodiments, the processor 1201 includes a hash unit and a writing unit, and the storage 1202 includes at least one first storage block.

The hash unit is configured to determine, for any third sub-request, a first storage block corresponding to the any third sub-request, and the write request includes at least one third sub-request.

The writing unit is configured to write weight attribute data or feature map attribute data corresponding to the any third sub-request into the first storage block corresponding to the any third sub-request.

A function of the first status register, a function of the second status register, a function of the reference status register, and a function of the determining unit may be implemented through the arbiter unit shown in FIG. 7. A function of the above-mentioned hash unit may be implemented through the hash unit shown in FIG. 7. A function of the above-mentioned reading unit may be implemented through the scheduler and the selection unit shown in FIG. 8. A function of the above-mentioned acquisition unit may be implemented through the acquisition unit shown in FIG. 7. A function of the above-mentioned conflict detection unit may be implemented through the conflict detection unit shown in FIG. 7. A function of the second storage block may be implemented through the second storage block shown in FIG. 7. A function of the above-mentioned writing unit may be implemented through the scheduler shown in FIG. 8.

The system provided in FIG. 12 above belongs to the same idea as the method embodiment. Details may refer to the method embodiment. The contents of the system provided in FIG. 12 corresponding to FIG. 7 and FIG. 8 may refer to the descriptions of FIG. 7 and FIG. 8.

The above-mentioned system characterizes the status of the weight attribute register in the systolic array through the reference status identification. The weight attribute data stored in the storage is written to the systolic array in response to the first weight read request in a case that the reference status identification satisfies the first pre-defined condition. The feature map attribute data stored in the storage is written to the systolic array in response to the first feature map read request in a case that the reference status identification satisfies the second pre-defined condition. The reference status identification may use fewer registering resources relative to the registering resources used by the queue. The system may be applied to a chip. The fewer the registering resources, the smaller the chip area. The chip is provided with a condition of reducing the chip area.

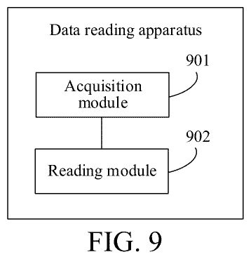

FIG. 9 is a schematic structural diagram of a data reading apparatus according to some embodiments. As shown in FIG. 9, the apparatus includes:
an acquisition module 901 configured to acquire a first weight read request and a first feature map read request, the first weight read request being configured for requesting to read weight attribute data from a storage, and the first feature map read request being configured for requesting to read feature map attribute data from the storage;
the acquisition module 901 being further configured to acquire a reference status identification, the reference status identification being configured for characterizing a status of a weight attribute register in a systolic array after a pre-defined elapsed time from a current time, and the weight attribute register being configured to register the weight attribute data; and
a reading module 902 configured to read the weight attribute data stored in the storage to the systolic array in response to the first weight read request in a case that the reference status identification satisfies a first pre-defined condition;
the reading module 902 being further configured to read the feature map attribute data stored in the storage to the systolic array in response to the first feature map read request in a case that the reference status identification satisfies a second pre-defined condition, the systolic array being configured to perform a calculation based on the weight attribute data and the feature map attribute data.

In some embodiments, the reference status identification satisfying a first pre-defined condition is as follows: the reference status identification characterizes that the weight attribute register is in a status of waiting to register the weight attribute data after the pre-defined elapsed time from the current time.

The reference status identification satisfying a second pre-defined condition is as follows: the reference status identification characterizes that the weight attribute register is in a status of completely registering the weight attribute data after the pre-defined elapsed time from the current time.

In some embodiments, the acquisition module 901 is further configured to acquire a first status identification, the first status identification characterizing whether the weight attribute register completely registers weight attribute data of a predetermined number of clock cycles after the pre-defined elapsed time from the current time.

The apparatus further includes:
a determining module configured to determine that the reference status identification characterizes that the weight attribute register is in the status of completely registering the weight attribute data after the pre-defined elapsed time from the current time in a case that the first status identification characterizes that the weight attribute register completely registers the weight attribute data of the predetermined number of clock cycles after the pre-defined elapsed time from the current time.

In some embodiments, the acquisition module 901 is further configured to acquire a second status identification, the second status identification characterizing whether the weight attribute data in the weight attribute register is calculated with feature map attribute data of a first clock cycle after the pre-defined elapsed time from the current time.

The apparatus further includes:
a determining module configured to determine that the reference status identification characterizes that the weight attribute register is in the status of waiting to register the weight attribute data after the pre-defined elapsed time from the current time in a case that the second status identification characterizes that the weight attribute data in the weight attribute register is calculated with the feature map attribute data of the first clock cycle after the pre-defined elapsed time from the current time.

In some embodiments, the acquisition module 901 is further configured to acquire a second weight read request and a second feature map read request, the second weight read request is configured for requesting to read the weight attribute data from the storage, and the second feature map read request is configured for requesting to read the feature map attribute data from the storage.

The reading module 902 is further configured to read the weight attribute data stored in the storage to the systolic array based on the second weight read request; and read the feature map attribute data stored in the storage to the systolic array based on the second feature map read request, a read delay of the weight attribute data and a read delay of the feature map attribute data each being the pre-defined elapsed time.

In some embodiments, the first weight read request includes at least one first weight sub-request, and the storage includes at least one first storage block.

The reading module 902 is configured to determine, for any first weight sub-request, a first storage block corresponding to the any first weight sub-request in a case that the any first weight sub-request is a valid request, and read weight attribute data corresponding to the any first weight sub-request from the first storage block corresponding to the any first weight sub-request; and transmit weight attribute data corresponding to first weight sub-requests to the systolic array.

In some embodiments, the apparatus further includes:
an extraction module configured to extract an address of the first storage block corresponding to the any first weight sub-request from the any first weight sub-request; and
a determining module configured to determine that the any first weight sub-request is a valid request when the address of the first storage block corresponding to the any first weight sub-request is different from an address of a first storage block corresponding to a reference first weight sub-request, the reference first weight sub-request being a first weight sub-request except the any first weight sub-request in a plurality of first weight sub-requests.

In some embodiments, any first storage block includes at least one second storage block.

The read module 902 is configured to determine a second storage block corresponding to the any first weight sub-request; and read the weight attribute data corresponding to the any first weight sub-request from the second storage block corresponding to the any first weight sub-request.

In some embodiments, the acquisition module 901 is further configured to acquire a write request, the write request is used for writing third data into the storage, and the third data is weight attribute data or feature map attribute data.

The apparatus further includes:
a writing module configured to write weight attribute data or feature map attribute data corresponding to the write request into the storage.

In some embodiments, the write request includes at least one third sub-request, and the storage includes at least one first storage block.

The writing module is configured to determine, for any third sub-request, a first storage block corresponding to the any third sub-request; and write weight attribute data or feature map attribute data corresponding to the any third sub-request into the first storage block corresponding to the any third sub-request.

The above-mentioned apparatus characterizes the status of the weight attribute register in the systolic array through the reference status identification. The weight attribute data stored in the storage is written to the systolic array in response to the first weight read request in a case that the reference status identification satisfies the first pre-defined condition. The feature map attribute data stored in the storage is written to the systolic array in response to the first feature map read request in a case that the reference status identification satisfies the second pre-defined condition. The reference status identification may use fewer registering resources relative to the registering resources used by the queue. The apparatus may be applied to a chip. The fewer the registering resources, the smaller the chip area. The chip is provided with a condition of reducing the chip area.

When the apparatus provided in FIG. 9 implements the functions of the apparatus, only division of the foregoing function modules is used as an example for description. In the practical application, the above-mentioned functions may be allocated to and completed by different function modules. An internal structure of the device is divided into different function modules to complete all or some of the functions described above. The apparatus provided in some embodiments belongs to the same idea as the method embodiment. Details of some embodiments may refer to the method embodiment.

According to some embodiments, each module or unit may exist respectively or be combined into one or more units. Some modules or units may be further split into multiple smaller function subunits, thereby implementing the same operations without affecting the technical effects of some embodiments. The modules or units are divided based on logical functions. In actual applications, a function of one module or unit may be realized by multiple modules or units, or functions of multiple modules or units may be realized by one module or unit. In some embodiments, the apparatus may further include other modules or units. In actual applications, these functions may also be realized cooperatively by the other modules or units, and may be realized cooperatively by multiple modules or units.

A person skilled in the art would understand that these “modules” or “units” could be implemented by hardware logic, a processor or processors executing computer software code, or a combination of both. The “modules” or “units” may also be implemented in software stored in a memory of a computer or a non-transitory computer-readable medium, where the instructions of each unit are executable by a processor to thereby cause the processor to perform the respective operations of the corresponding module or unit.

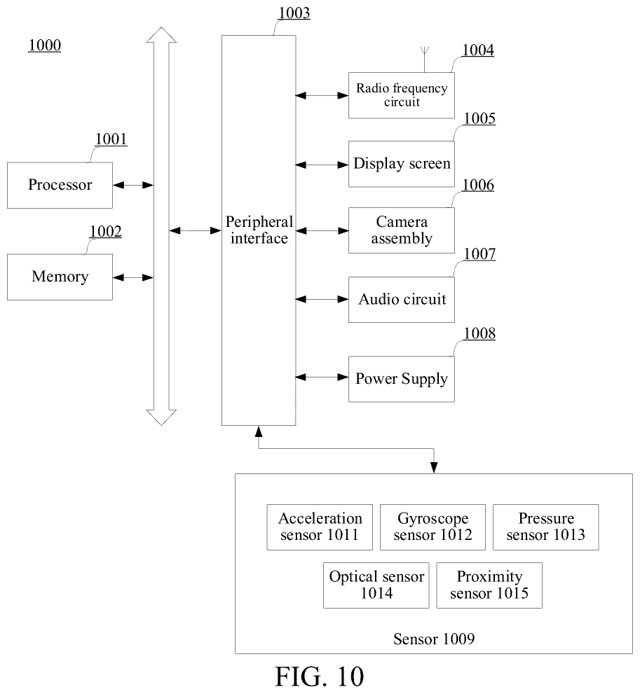

FIG. 10 is a structural block diagram of a terminal device 1000 according to some embodiments. The terminal device 1000 includes: a processor 1001 and a memory 1002.

The processor 1001 may include one or more processing cores, for example, a 4-core processor or an 8-core processor. The processor 1001 may be implemented in at least one hardware form of digital signal processing (DSP), a field-programmable gate array (FPGA), and a programmable logic array (PLA). The processor 1001 may also include a main processor and a coprocessor. The main processor is a processor configured to process data in an awake status and is also referred to as a central processor (CPU). The coprocessor is a low-power-consumption processor configured to process data in a standby status. In some embodiments, the processor 1001 may be integrated with a graphics processor (GPU). The GPU is configured to render and draw content that may be displayed on a display screen. In some embodiments, the processor 1001 may further include an AI processor. The AI processor is configured to process computing operations related to machine learning.

The memory 1002 may include one or more computer-readable storage media. The computer-readable storage medium may be non-transient. The memory 1002 may further include a high-speed random access memory and a nonvolatile memory, for example, one or more disk storage devices or flash storage devices. In some embodiments, the non-transient computer-readable storage medium in the memory 1002 is configured to store at least one computer-readable instruction. The at least one computer-readable instruction is configured to be executed by the processor 1001 to implement the data reading method provided in the method embodiments of this application.

In some embodiments, the terminal device 1000 may further include: a peripheral device interface 1003 and at least one peripheral device. The processor 1001, the memory 1002, and the peripheral device interface 1003 may be connected through a bus or a signal line. Each peripheral device may be connected to the peripheral device interface 1003 through a bus, a signal line, or a circuit board. The peripheral device includes: at least one of a radio frequency (RF) circuit 1004, a display screen 1005, a camera assembly 1006, an audio circuit 1007, or a power supply 1008.

The peripheral device interface 1003 may be configured to connect at least one peripheral device related to input/output (I/O) to the processor 1001 and the memory 1002. In some embodiments, the processor 1001, the memory 1002, and the peripheral device interface 1003 are integrated on the same chip or circuit board. In some embodiments, any one or two of the processor 1001, the memory 1002, and the peripheral device interface 1003 may be implemented on a single chip or circuit board. This is not limited in some embodiments.

The RF circuit 1004 is configured to receive and transmit an RF signal, also referred to as an electromagnetic signal. The RF circuit 1004 communicates with a communication network and other communication devices through the electromagnetic signal. The RF circuit 1004 converts an electrical signal into an electromagnetic signal for transmission, or converts a received electromagnetic signal into an electrical signal. In some embodiments, the RF circuit 1004 includes: an antenna system, an RF transceiver, one or more amplifiers, a tuner, an oscillator, a digital signal processor, a codec chipset, a user identity module card, and the like. The RF circuit 1004 may communicate with another terminal through at least one wireless communication protocol. The wireless communication protocol includes but is not limited to a world wide web, a metropolitan area network, an intranet, various generations of mobile communication networks (2G, 3G, 4G, and 5G), a wireless local area network, and/or a wireless fidelity (WiFi) network. In some embodiments, the RF 1004 may further include a circuit related to near field communication (NFC). However, the disclosure is not limited thereto.

The display screen 1005 is configured to display a user interface (UI). The UI may include a graph, text, an icon, a video, and any combination thereof. When the display screen 1005 is a touch display screen, the display screen 1005 further has a capability of acquiring a touch signal on or above a surface of the display screen 1005. The touch signal may be input to the processor 1001 as a control signal for processing. The display screen 1005 may be further configured to provide a virtual button and/or a virtual keyboard, referred to as a soft button and/or a soft keyboard. In some embodiments, one display screen 1005 may be provided on a front panel of the terminal device 1000. In some embodiments, there may be at least two display screens 1005 provided on different surfaces of the terminal device 1000 or in a folded design. In some embodiments, the display screen 1005 may be a flexible display screen provided on a curved surface or a folded surface of the terminal device 1000. Even, the display screen 1005 may be further provided in a non-rectangular irregular pattern. The display screen 1005 may be prepared using materials such as a liquid crystal display (LCD) and an organic light-emitting diode (OLED).

The camera assembly 1006 is configured to acquire images or videos. In some embodiments, the camera assembly 1006 includes a front camera and a rear camera. The front camera is provided on the front panel of the terminal, and the rear camera is provided on a back surface of the terminal. In some embodiments, there are at least two rear cameras, which are any of main cameras, depth-of-field cameras, wide-angle cameras, and telephoto cameras, to achieve a background blur function through fusion of the main camera and the depth-of-field camera, panoramic photographing and virtual reality (VR) photographing functions through fusion of the main camera and the wide-angle camera, or other fusion photographing functions. In some embodiments, the camera assembly 1006 may further include a flash. The flash may be a monochrome temperature flash, or may be a double color temperature flash. The double color temperature flash refers to a combination of a warm light flash and a cold light flash, and may be configured for light compensation under different color temperatures.

The audio circuit 1007 may include a microphone and a speaker. The microphone is configured to acquire sound waves of a user and an environment, and convert the sound waves into electrical signals to input to the processor 1001 for processing, or input to the RF circuit 1004 for implementing voice communication. For the purpose of stereo acquisition or noise reduction, there may be a plurality of microphones, provided at different portions of the terminal device 1000. The microphone may further be an array microphone or an omni-directional acquisition type microphone. The speaker is configured to convert the electrical signals from the processor 1001 or the RF circuit 1004 into sound waves. The speaker may be a film speaker, or may be a piezoelectric ceramic speaker. When the speaker is the piezoelectric ceramic speaker, the speaker may not only convert the electrical signal into a sound wave audible to the human being, but also convert the electrical signal into a sound wave inaudible to the human being, for ranging and other purposes. In some embodiments, the audio circuit 1007 may further include an carphone jack.

The power supply 1008 is configured to supply power to assemblies in the terminal device 1000. The power supply 1008 may be an alternating current, a direct current, a disposable battery, or a rechargeable battery. When the power supply 1008 includes a rechargeable battery, the rechargeable battery may be a wired rechargeable battery or a wireless rechargeable battery. The wired rechargeable battery is a battery charged through a wired line, and the wireless rechargeable battery is a battery charged through a wireless coil. The rechargeable battery may be further configured to support a fast charging technology.

In some embodiments, the terminal device 1000 further includes one or more sensors 1009. The one or more sensors 1009 include, but are not limited to, an acceleration sensor 1011, a gyroscope sensor 1012, a pressure sensor 1013, an optical sensor 1014, and a proximity sensor 1015.

The acceleration sensor 1011 may detect magnitudes of accelerations on three coordinate axes of a coordinate system established with the terminal device 1000. For example, the acceleration sensor 1011 may be configured to detect components of gravity acceleration on the three coordinate axes. The processor 1001 may control the display screen 1005 to display the UI in a landscape view or a portrait view according to a gravity acceleration signal acquired by the acceleration sensor 1011. The acceleration sensor 1011 may be further configured to acquire motion data of a game or a user.

The gyroscope sensor 1012 may detect a body direction and a rotation angle of the terminal device 1000. The gyroscope sensor 1012 may cooperate with the acceleration sensor 1011 to acquire a 3D action by the user on the terminal device 1000. The processor 1001 may realize the following functions according to the data acquired by the gyroscope sensor 1012: action sensing (such as changing the UI according to a tilt operation of the user), image stabilization during photographing, game control, and inertial navigation.

The pressure sensor 1013 may be provided at a side frame of the terminal device 1000 and/or a lower layer of the display screen 1005. When the pressure sensor 1013 is provided at the side frame of the terminal device 1000, a holding signal of the user on the terminal device 1000 may be detected. The processor 1001 performs left and right hand recognition or a quick operation according to the holding signal acquired by the pressure sensor 1013. When the pressure sensor 1013 is provided on the low layer of the display screen 1005, the processor 1001 controls an operable control on the UI according to a pressure operation of the user on the display screen 1005. The operable control includes at least one of a button control, a scroll-bar control, an icon control, and a menu control.

The optical sensor 1014 is configured to acquire ambient light intensity. In some embodiments, the processor 1001 may control the display brightness of the display screen 1005 according to the ambient light intensity acquired by the optical sensor 1014. When the ambient light intensity is high, the display brightness of the display screen 1005 is increased. When the ambient light intensity is low, the display brightness of the display screen 1005 is decreased. In some embodiments, the processor 1001 may further dynamically adjust photographing parameters of the camera assembly 1006 according to the ambient light intensity acquired by the optical sensor 1014.

The proximity sensor 1015, also referred to as a distance sensor, is provided on the front panel of the terminal device 1000. The proximity sensor 1015 is configured to acquire a distance between the user and a front surface of the terminal device 1000. In some embodiments, when the proximity sensor 1015 detects that the distance between the user and the front surface of the terminal device 1000 gradually decreases, the display screen 1005 is controlled by the processor 1001 to switch from a screen-on status to a screen-off status. When the proximity sensor 1015 detects that the distance between the user and the front surface of the terminal device 1000 gradually increases, the display screen 1005 is controlled by the processor 1001 to switch from the screen-off status to the screen-on status.

A person skilled in the art may understand that the structure shown in FIG. 10 constitutes no limitation on the terminal device 1000, and the terminal device may include more or fewer assemblies than those shown in the figure, or a combination of some assemblies, or have a different arrangement of assemblies.

FIG. 11 is a schematic structural diagram of a server according to some embodiments. The server 1100 may vary greatly due to different configurations or performances and may include one or more processors 1101 and one or more memories 1102. The one or more memories 1102 have at least one computer-readable instruction stored therein. The at least one computer-readable instruction is loaded and executed by the one or more processors 1101 to implement the data reading method provided in some embodiments. Illustratively, the processor 1101 is a CPU. The server 1100 may further have components such as a wired or wireless network interface, a keyboard, and an I/O interface for inputting and outputting. The server 1100 may further include other components configured to implement device functions, and details are not described herein.

According to some embodiments, a computer-readable storage medium is further provided, having at least one computer-readable instruction stored therein. The at least one computer-readable instruction is loaded and executed by a processor to cause an electronic device to implement the data reading method according to any one of the foregoing aspects.

In some embodiments, the above-mentioned computer-readable storage medium may be a read-only memory (ROM), a random access memory (RAM), a compact disc read-only memory (CD-ROM), a magnetic tape, a floppy disk, an optical data storage device, or the like.

According to some embodiments, a computer program product is further provided, having at least one computer-readable instruction stored therein. The at least one computer-readable instruction is loaded and executed by a processor to cause an electronic device to implement the data reading method according to any one of the foregoing aspects.

“A plurality of” mentioned herein refers to two or more. “And/or” describes an association relationship of associated objects and represents that three relationships may exist. For example, A and/or B may represent the following three cases: only A exists, both A and B exist, and only B exists. The character “/” indicates an “or” relationship between the associated objects.

The foregoing embodiments are used for describing, instead of limiting the technical solutions of the disclosure. A person of ordinary skill in the art shall understand that although the disclosure has been described in detail with reference to the foregoing embodiments, modifications can be made to the technical solutions described in the foregoing embodiments, or equivalent replacements can be made to some technical features in the technical solutions, provided that such modifications or replacements do not cause the essence of corresponding technical solutions to depart from the spirit and scope of the technical solutions of the embodiments of the disclosure and the appended claims.

What is claimed is:

1. A data reading method, performed by an electronic device including a processor, a systolic array for performing calculations based on weight attribute data and feature map attribute data and a storage, wherein the systolic array comprises a weight attribute register for registering the weight attribute data, the data reading method comprising:
acquiring a first weight read request for requesting to read the weight attribute data from the storage, and a first feature map read request for requesting to read the feature map attribute data from the storage;
acquiring a reference status identification indicating a status of the weight attribute register in the systolic array after a pre-defined elapsed time;
based on the reference status identification satisfying a first pre-defined condition:
reading the weight attribute data from the storage, and
writing the weight attribute data to the systolic array in response to the first weight read request; and
based on the reference status identification satisfying a second pre-defined condition:
reading the feature map attribute data from the storage, and
writing the feature map attribute data to the systolic array in response to the first feature map read request.

2. The data reading method according to claim 1, wherein the first pre-defined condition is satisfied based on the reference status identification indicating the weight attribute register is in a first status of waiting to register the weight attribute data after the pre-defined elapsed time from a current time.

3. The data reading method according to claim 2, wherein the second pre-defined condition is satisfied based on the reference status identification indicating the weight attribute register is in a second status of completely registering the weight attribute data after the pre-defined elapsed time from the current time.

4. The data reading method according to claim 2, further comprising:
acquiring a first status identification indicating the weight attribute register completely registers first weight attribute data, in the weight attribute register, of a predetermined number of clock cycles after the pre-defined elapsed time from the current time; and
determining, based on the first status identification, that the reference status identification indicates the weight attribute register is in a second status of completely registering the weight attribute data after the pre-defined elapsed time from the current time.

5. The data reading method according to claim 3, further comprising:
acquiring a second status identification indicating second weight attribute data, in the weight attribute register, is calculated with first feature map attribute data of a first clock cycle after the pre-defined elapsed time from the current time; and
determining, based on the second status identification, that the reference status identification indicates the weight attribute register is in the first status.

6. The data reading method according to claim 1, further comprising:
acquiring a second weight read request to read the weight attribute data from the storage and a second feature map read request to read the feature map attribute data from the storage;
based on the second weight read request:
reading the weight attribute data from the storage, and
writing the weight attribute data to the systolic array; and
based on the second feature map read request:
reading the feature map attribute data from the storage, and
writing the feature map attribute data to the systolic array,
wherein a first read delay of the weight attribute data and a second read delay of the feature map attribute data are the pre-defined elapsed time.

7. The data reading method according to claim 1, wherein the first weight read request comprises at least one first weight sub-request, and the storage comprises at least one first storage block, and
wherein the reading the weight attribute data from the storage and writing the weight attribute data to the systolic array comprises:
determining, for a first valid weight sub-request from among the at least one first weight sub-request, a first block, from among the at least one first storage block, corresponding to the first valid weight sub-request, and
reading first weight attribute data corresponding to the first valid weight sub-request from the first block; and
transmitting, to the systolic array, second weight attribute data corresponding to the at least one first weight sub-request, wherein the second weight attribute data comprises the first weight attribute data.

8. The data reading method according to claim 7, wherein the at least one first weight sub-request comprises a plurality of first weight sub-requests, and
wherein the reading the weight attribute data from the storage and writing the weight attribute data to the systolic array further comprises:
extracting a first address of the first block from the first valid weight sub-request; and
determining that the first valid weight sub-request is a valid request based on the first address being different from a second address of a different first storage block corresponding to a reference first weight sub-request comprising at least one different first weight sub-request from among the plurality of first weight sub-requests.

9. The data reading method according to claim 7, wherein a different first storage block, from among the at least one first storage block, comprises at least one second storage block, and
wherein the reading the first weight attribute data comprises:
determining a second block, from among the at least one second storage block, corresponding to the first valid weight sub-request; and
reading the first weight attribute data from the second block.

10. The data reading method according to claim 1, further comprising:
acquiring a write request for writing at least one from among the weight attribute data and the feature map attribute data into the storage; and
writing first weight attribute data or first feature map attribute data, corresponding to the write request, to the storage.

11. A storage system, comprising:
a storage configured to store weight attribute data and feature map attribute data;
a systolic array comprising a weight attribute register and that is configured to perform calculations based on the weight attribute data and the feature map attribute data; and
a processor operatively connected to the storage and the systolic array, wherein the processor is configured to:
acquire a first weight read request for requesting to read the weight attribute data from the storage and a first feature map read request for requesting to read the feature map attribute data from the storage;
acquire a reference status identification indicating a status of the weight attribute register in the systolic array after a pre-defined elapsed time;
based on the reference status identification satisfying a first pre-defined condition:
read the weight attribute data from the storage, and
write the weight attribute data to the systolic array in response to the first weight read request; and
based on the reference status identification satisfying a second pre-defined condition:
read the feature map attribute data from the storage, and
write the feature map attribute data to the systolic array based on the first feature map read request.

12. The storage system according to claim 11, wherein the first pre-defined condition is satisfied based on the reference status identification indicating the weight attribute register is in a first status of waiting to register the weight attribute data after the pre-defined elapsed time from a current time.

13. The storage system according to claim 12, wherein the second pre-defined condition is satisfied based on the reference status identification indicating the weight attribute register is in a second status of completely registering the weight attribute data after the pre-defined elapsed time from the current time.

14. The storage system according to claim 12, wherein the processor comprises a first status register, a reference status register, and wherein the storage system further comprises memory configured to store computer program code,
wherein the processor is further configured to read the program code and operate as instructed by the program code,
wherein the first status register is configured to register a first status identification indicating whether the weight attribute register completely registers first weight attribute data, in the weight attribute register, of a predetermined number of clock cycles after the pre-defined elapsed time from the current time,
wherein the reference status register is configured to register the reference status identification, and
wherein the program code comprises first determining code configured to cause the processor to:
acquire the first status identification, wherein the first status identification indicates the weight attribute register completely registers the first weight attribute data; and
determine, based on the first status identification, that the reference status identification indicates the weight attribute register is in a second status of completely registering the weight attribute data after the pre-defined elapsed time from the current time.

15. The storage system according to claim 13, wherein the processor comprises a second status register, a reference status register, and wherein the storage system further comprises memory configured to store computer program code,
wherein the processor is further configured to read the program code and operate as instructed by the program code,
wherein the second status register is configured to register a second status identification indicating whether second weight attribute data, in the weight attribute register, is calculated with first feature map attribute data of a first clock cycle after the pre-defined elapsed time from the current time,
wherein the reference status register is configured to register the reference status identification, and
wherein the program code comprises second determining code configured to cause the processor to:
acquire the second status identification, wherein the second status identification indicates the second weight attribute data is calculated with the first feature map attribute data; and
determine, based on the second status identification, that the reference status identification indicates the weight attribute register is in the first status.

16. The storage system according to claim 11, wherein the processor is further configured to:
acquire a second weight read request to read the weight attribute data from the storage and a second feature map read request to read the feature map attribute data from the storage;
based on the second weight read request:
read the weight attribute data stored in the storage, and
write the weight attribute data to the systolic array; and
based on the second feature map read request:
read the feature map attribute data from the storage, and
write the feature map attribute data to the systolic array, and
wherein a first read delay of the weight attribute data and a second read delay of the feature map attribute data each are the pre-defined elapsed time.

17. The storage system according to claim 11, wherein the first weight read request comprises at least one first weight sub-request, and the storage comprises at least one first storage block,
wherein the storage system further comprises memory configured to store computer program code, and
wherein the processor is further configured to read the program code and operate as instructed by the program code, the program code comprising:
hash code configured to cause the processor to determine, for a first valid weight sub-request from among the at least one first weight sub-request, a first block, from among the at least one first storage block, corresponding to the first valid weight sub-request;
reading code configured to cause the processor to read first weight attribute data corresponding to the first valid weight sub-request from the first block; and
acquisition code configured to cause the processor to transmit, to the systolic array, second weight attribute data corresponding to the at least one first weight sub-request, wherein the second weight attribute data comprises the first weight attribute data.

18. The storage system according to claim 17, wherein the at least one first weight sub-request comprises a plurality of first weight sub-requests, and
wherein the program code further comprises conflict detection code configured to cause the processor to:
extract a first address of the first block from the first valid weight sub-request; and
determine that the first valid weight sub-request is a valid request based on the first address being different from a second address of a different first storage block corresponding to a reference first weight sub-request comprising at least one different first weight sub-request from among the plurality of first weight sub-requests.

19. The storage system according to claim 17, wherein a different first storage block, from among the at least one first storage block, comprises at least one second storage block,
wherein the at least one second storage block is configured to store the weight attribute data and the feature map attribute data, and
wherein the reading code is configured to cause the processor to:
determine a second block, from among the at least one second storage block, corresponding to the first valid weight sub-request; and
read the first weight attribute data from the second block.

20. A non-transitory computer-readable storage medium, storing computer code which, when executed by at least one processor, causes the at least one processor to at least:
acquire a first weight read request for requesting to read weight attribute data from storage, and a first feature map read request for requesting to read feature map attribute data from the storage;
acquire a reference status identification indicating a status of a weight attribute register in a systolic array after a pre-defined elapsed time;
based on the reference status identification satisfying a first pre-defined condition:
read the weight attribute data from the storage, and
write the weight attribute data to the systolic array in response to the first weight read request; and
based on the reference status identification satisfying a second pre-defined condition:
read the feature map attribute data from the storage, and
write the feature map attribute data to the systolic array in response to the first feature map read request.
